(19) United States
(12) Patent Application Publication
(10) Pub. No.: US 2026/0020404 A1
(43) Pub. Date: Jan. 15, 2026

(54) DISPLAY APPARATUS AND MANUFACTURING METHOD THEREOF

(71) Applicant: LG Display Co., Ltd., Seoul (KR)

(72) Inventors: Seong Ho AHN, Paju-si (KR); Dong Kwan HYUN, Paju-si (KR); Hyoung Sun PARK, Paju-si (KR); Hyun Seok NA, Paju-si (KR); Pyung Ho CHOI, Paju-si (KR)

(73) Assignee: LG Display Co., Ltd., Seoul (KR)

(21) Appl. No.: 19/222,359

(22) Filed: May 29, 2025

(30) Foreign Application Priority Data
Jul. 10, 2024 (KR) 10-2024-0091192

(51) Int. Cl. H10H 29/30; H10H 29/01; H10H 29/49

(52) U.S. Cl. CPC H10H 29/352; H10H 29/012; H10H 29/49

(57) ABSTRACT

The present specification discloses a display device and a manufacturing method thereof. A display device according to an embodiment of the present specification includes a display region including a light-emitting element and a second electrode disposed on the light-emitting element, and a non-display region including a first dummy light-emitting element and a third electrode disposed on the first dummy light-emitting element, and surrounding the display region, wherein the non-display region further includes a second dummy light-emitting element disposed between a border of the non-display region and the first dummy light-emitting element. According to the present specification, information items for a light-emitting element of a display panel may be easily extracted.

### CROSS-REFERENCE TO RELATED APPLICATION

This application claims priority to and the benefit of Korean Patent Application No. 10-2024-0091192, filed on Jul. 10, 2024, the disclosure of which is incorporated herein by reference in its entirety.

### BACKGROUND

### Technical Field

The present specification relates to a display apparatus.

### Description of the Related Art

Display devices are being applied to various electronic devices such as a television (TV), a mobile phone, a notebook, a tablet, and the like.

Display devices include an organic light-emitting display (OLED) device which emits light by itself, a liquid crystal display (LCD) device which requires a separate light source, and the like.

Recently, display devices including light-emitting elements (light-emitting diodes, LEDs) are attracting attention as next generation display devices. The light-emitting elements are formed of an inorganic material rather than an organic material, and thus the display devices including light-emitting elements may have a faster lighting speed and higher emission efficiency, and display an image of higher brightness compared to an LCD device or OLED device.

Meanwhile, the inspection is required in a production process of a display device to determinate whether a product is normally produced such as lighting, brightness, stability, and the like. Although it is possible to inspect a display device in a state of a finished product to determine whether a product has been normally produced, it is advantageous to perform an inspection every time a specific operation is performed in a manufacturing process to identify a cause of a problem and take additional measures before moving on to a next process for defects by in terms of yield of high-quality final products. Accordingly, design of a display device for easily extracting key quality management information items (critical to quality, CTQ), data to be measured, and the like is required.

### BRIEF SUMMARY

The present disclosure is directed to a display technique where, data to be measured can be easily extracted in a manufacturing process of a display device including an inorganic light-emitting element (for example, a micro light-emitting diode, micro LED).

An embodiment of the present specification is directed to providing a display device capable of easily extracting key quality management information items in a manufacturing process.

The features according to embodiments of the present specification are not limited to the above-described features, and other features that are not mentioned will be clearly understood by those skilled in the art from the following description.

A display device according to an embodiment of the present specification includes a display region including a light-emitting element and a second electrode disposed on the light-emitting element, and a non-display region including a first dummy light-emitting element and a third electrode disposed on the first dummy light-emitting element, and surrounding the display region, wherein the non-display region further includes a second dummy light-emitting element disposed between a border of the non-display region and the first dummy light-emitting element.

A display device according to an embodiment of the present specification includes a display region including a plurality of pixels, and a non-display region including a first dummy pixel and a second dummy pixel and surrounding the display region, wherein each of the plurality of pixels includes a first subpixel including a 1-1 subpixel and a 1-2 subpixel that implement a first color, a second subpixel including a 2-1 subpixel and a 2-2 subpixel that implement a second color, and a third subpixel including a 3-1 subpixel and a 3-2 subpixel that implement a third color, the first dummy pixel includes a first dummy light-emitting element and a third electrode disposed on the first dummy light-emitting element, and the second dummy pixel is disposed between a border of the non-display region and the first dummy pixel.

A method of manufacturing the display device according to an embodiment of the present specification comprises inspecting whether a defect of the light-emitting element is presented or not in each specific operation of a manufacturing process of the display device; and if the defect is presented, then removing the defect before moving on to a next process, wherein the inspecting whether the defect is presented or not comprises inferring a physical property value of the light-emitting element based on measurement of a physical property value of the first dummy light-emitting element.

Specific details according to the various examples of the present specification other than solutions to the above-mentioned problems are included in the description and drawings described below.

### BRIEF DESCRIPTION OF THE SEVERAL VIEWS OF THE DRAWINGS

The following drawings attached to this specification illustrate example embodiments of the present disclosure and, together with the detailed description of the disclosure to be described below, serve to further understand the technical idea of the present disclosure, and therefore the present disclosure should not be construed as being limited to matters described in such drawings, in which:

FIG. 1 is an exploded perspective view showing a display device according to an embodiment of the present specification;

FIG. 2 is a plan view showing the display device according to the embodiment of the present specification;

FIG. 3 is a plan view showing the display device according to the embodiment of the present specification;

FIG. 4 is a block diagram showing a display panel according to the embodiment of the present specification;

FIGS. 5 to 7 are plan views showing the display device according to the embodiment of the present specification;

FIGS. 8 to 10 are plan views showing the display device according to the embodiment of the present specification;

FIG. 11 is an enlarged view showing the display device according to the embodiment of the present specification;

FIG. 12 is a view showing a circuit structure according to the embodiment of the present specification;

FIGS. 13 to 16 are cross-sectional views showing the display device according to the embodiment of the present specification;

FIG. 17 is a cross-sectional view showing the display device according to the embodiment of the present specification;

FIG. 18 is a cross-sectional view showing the display device according to the embodiment of the present specification;

FIGS. 19 to 21 are plan views showing the display device according to the embodiment of the present specification;

FIG. 22 is a plan view showing the display device according to the embodiment of the present specification before being trimmed (before a trimming process);

FIG. 23 is a plan view showing the display device according to the embodiment of the present specification after being trimmed (after the trimming process);

FIGS. 24 and 25 are cross-sectional views showing the display device according to the embodiment of the present specification; FIGS. 26 to 29 are plan views showing the display device according to the embodiment of the present specification;

FIG. 30 is a cross-sectional view showing the display device according to the embodiment of the present specification; and

FIGS. 31 to 34 are views showing devices to which the display device according to embodiments of the present specification is applied.

### DETAILED DESCRIPTION

Advantages and features of the present specification and methods of achieving them will become apparent with reference to the following embodiments, which are described in detail, in conjunction with the accompanying drawings. However, the present specification is not limited to the embodiments to be described below and may be implemented in various different forms, the embodiments are only provided to completely disclose the present specification and completely convey the scope of the present specification to those skilled in the art.

Since the shapes, sizes, proportions, angles, numbers, and the like disclosed in the drawings for describing the embodiments of the present specification are only exemplary, the present specification is not limited to the items shown in the drawings. The same reference number indicates the same components throughout the specification. Further, in describing the present specification, when it is determined that a detailed description of related known technology may unnecessarily obscure the gist of the present specification, the detailed description thereof will be omitted. When “providing,” “including,” “having,” “consisting of,” and the like mentioned in the present specification are used, other parts may be added unless ‘only’ is used. A case in which a component is expressed in a singular form may include a plural form unless explicitly stated otherwise.

In interpreting a component, the component is interpreted as including the margin of error even when there is no separate explicit description for the margin of error.

In a description of a positional relationship, when the positional relationship of two parts such as “on,” “at an upper portion,” “at a lower portion,” “next to,” “adjacent to,” or the like is described, one or more other parts may be located between two components unless “immediately”, “directly,” “close to” is used.

In a description of a temporal relationship, when the temporal relationship is described as “after,” “following,” “and then,” “before,” or the like, non-consecutive cases may also be included unless “immediately” or “directly” is used.

Although first, second, and the like are used to describe various components, these components are not limited by these terms. These terms are only used to distinguish one component from another component. Accordingly, a first component described below may also be a second component within the technical spirit of the present specification.

The terms, such as first, second, A, B, (a), and (b) may be used to describe components of the present specification. These terms are only for the purpose of distinguishing one component from another component, and the nature, sequence, order, or the like of the corresponding components is not limited by these terms.

When a component is described as being “connected,” “coupled,” “linked,” or “attached” to another component, it should be understood that the component may be directly connected, coupled, linked, or attached to the other component, but another component may be interposed between the components which may be indirectly connected, coupled, linked, or attached to each other unless explicitly stated otherwise.

When a component or layer is described as “in contact with” or “overlap” another component or layer, it should be understood that the component or layer may be in direct contact with or directly overlap another component or layer, but another component may be interposed between the components which may be in direct contact with or directly overlap each other unless explicitly stated otherwise.

“At least one” should be understood as including a combination of one or more of the related components. For example, the term “at least one of first, second, and third components” includes not only the first, second, or third component, but also all combinations of two or more of the first, second, and third components.

The terms “a first direction,” “a second direction,” “a third direction,” “an X-axis direction,” “a Y-axis direction,” and “a Z-axis direction” should not be understood as only a geometric relationship where a relationships therebetween are perpendicular to each other, but mean that a configuration of the present specification has a broader directionality within a range which may functionally acts.

Features of various embodiments of the present specification may be partially or entirely combined with each other, and technically, various linkages and operations are possible, and the embodiments may be implemented independently of each other or together in a related relationship.

Hereinafter, various embodiments of the present specification will be described in detail with reference to the accompanying drawings.

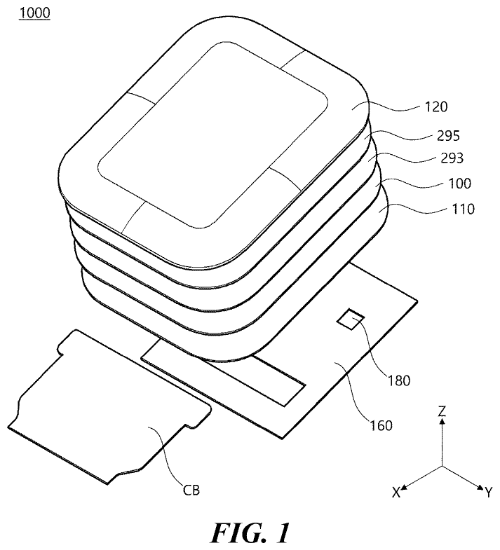

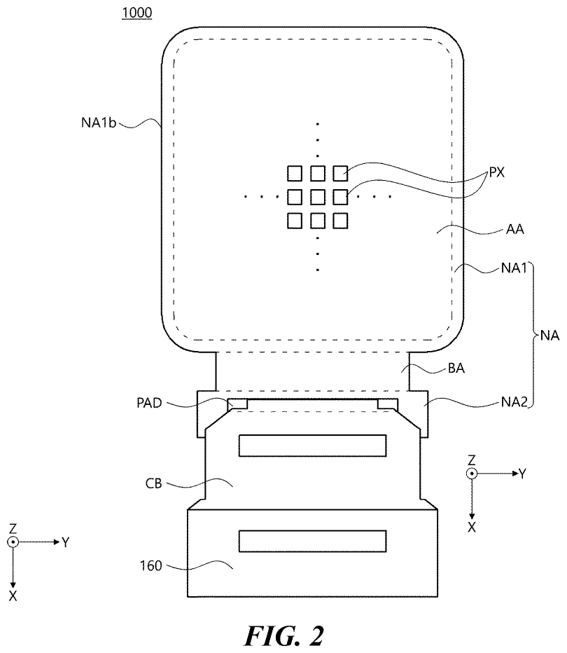

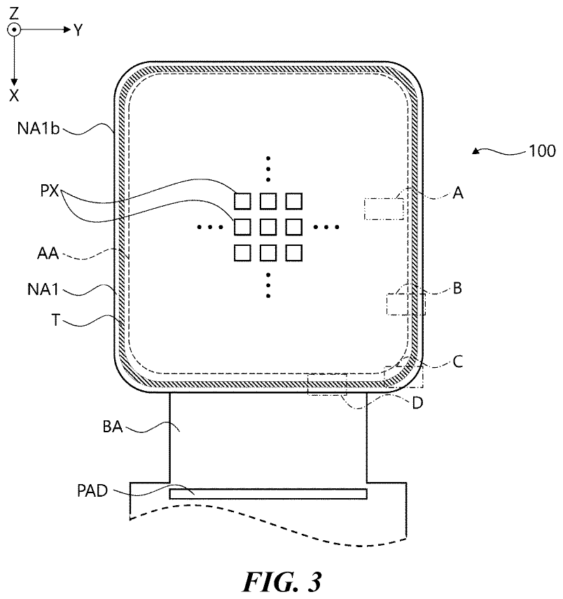

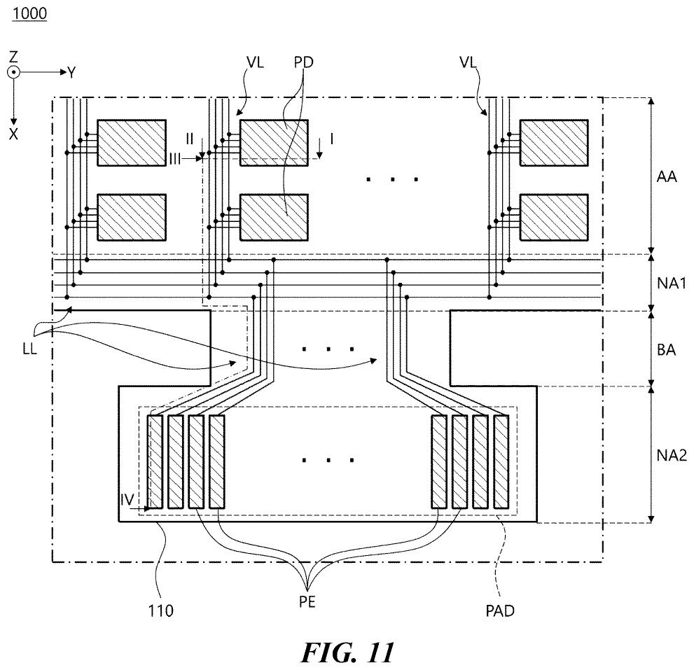

FIG. 1 is an exploded perspective view showing a display device according to an embodiment of the present specification. FIG. 2 is a plan view showing the display device according to the embodiment of the present specification. FIG. 3 is a plan view showing the display device according to the embodiment of the present specification. FIG. 11 is an enlarged view showing the display device according to the embodiment of the present specification.

Referring to FIGS. 1 to 3 and FIG. 11, a display device 1000 according to the embodiment of the present specification may include a display panel 100, a polarization layer 293, a second adhesive layer 295, a cover member 120, a support substrate 110, a flexible circuit board CB, and a printed circuit board 160.

For example, the display device 1000 may include a substrate 110. The substrate 110 may be a member which supports other components of the display device 1000. The substrate 110 may be formed of an insulating material. For example, the substrate 110 may be formed of glass, resin, or the like.

Further, the substrate 110 may be formed of a material having flexibility. For example, the substrate 110 may be formed of a plastic material having flexibility such as polyimide (PI), or the like. However, the embodiments of the present specification are not limited thereto.

The display panel 100 may implement information, a video, and/or an image provided to a user. For example, the display panel 100 may include a display region AA and a non-display region NA. For example, the substrate 110 may include the display region AA and the non-display region NA. The display region AA and the non-display region NA are not limited to the substrate 110 but may be described throughout the display device 1000.

The display region AA may be a region where an image is displayed. The display region AA may include a plurality of pixels PX. Each of the plurality of pixels PX may be composed of a plurality of subpixels. A plurality of light-emitting elements may be disposed in each of the plurality of subpixels. The plurality of light-emitting elements may be configured differently depending on the type of display device 1000. For example, when the display device 1000 is an inorganic light-emitting display device, the light-emitting element may be a light-emitting diode (LED), a micro light-emitting diode (micro LED), or a mini light-emitting diode (mini LED), but the embodiments of the present specification are not limited thereto.

The non-display region NA may be a region where an image is not displayed. Various lines and circuits for driving the plurality of pixels PX of the display region AA may be disposed in the non-display region NA. For example, in the non-display region NA, various lines and driving circuits may be mounted, and a pad portion PAD to which an integrated circuit, a printed circuit, and the like are connected may be disposed, but the embodiments of the present specification are not limited thereto.

For example, the driving circuit may be a data driving circuit and/or a gate driving circuit, but the embodiments of the present specification are not limited thereto. Lines to which control signals for controlling the driving circuits are supplied may be disposed on the display panel 100. For example, the control signals may include various timing signals including a clock signal, an input data enable signal, and synchronization signals, but the embodiments of the present specification are not limited thereto. The control signals may be received through the pad portion PAD. For example, link lines LL for transmitting signals may be disposed in the non-display region NA. For example, driving components such as the flexible circuit board CB and the printed circuit board 160 may be connected to the pad portion PAD.

According to the present specification, the non-display region NA may include a first non-display region NA1, a bending region BA, and a second non-display region NA2. For example, the first non-display region NAI may be a region surrounding at least a portion of the display region AA. The bending region BA may be a region extending from at least one side of a plurality of sides of the first non-display region NAI and may be a bendable region. The second non-display region NA2 may be a region extending from the bending region BA, and the pad portion PAD may be disposed in the second non-display region NA2. For example, the bending region BA may be in a bent state, and the remaining region of the substrate 110 excluding the bending region BA may be in a flat state. In this case, as the bending region BA is bent, the second non-display region NA2 may be located on a back surface of the display region AA. However, the embodiments of the present specification are not limited thereto.

A plurality of pixel driving circuits PD may be disposed in the display region AA. The plurality of pixel driving circuits PD may be circuits for driving light-emitting elements of the plurality of subpixels. Each of the plurality of pixel driving circuits PD includes a plurality of transistors including a driving transistor, a storage capacitor, and the like, and may control light-emitting operations of the plurality of light-emitting elements by supplying the control signals, power, and driving currents to the light-emitting elements of the plurality of subpixels. For example, the pixel driving circuit PD may include a power line and a signal line for controlling light-emitting on/off and/or light-emitting time of the light-emitting elements. For example, the plurality of pixel driving circuits PD may be driving drivers manufactured using a metal-oxide-silicon field effect transistor (MOSFET) manufacturing process on a semiconductor substrate, but the embodiments of the present specification are not limited thereto. The driving driver may include the plurality of pixel driving circuits PD and may drive the plurality of subpixels.

The flexible circuit board CB and the printed circuit board 160 may be disposed under the display panel 100. The flexible circuit board CB and the printed circuit board 160 may be disposed on an edge of at least one side of the display panel 100, but the embodiments of the present specification are not limited thereto. One side of the flexible circuit board CB may be attached to the display panel 100 and the other side may be attached to the printed circuit board 160, but the embodiments of the present specification are not limited thereto. The flexible circuit board CB may be a flexible film, but the embodiments of the present specification are not limited thereto.

The pad portion PAD including a plurality of pad electrodes PE may be disposed in the second non-display region NA2. A driving component including one or more flexible circuit boards (or flexible films) CB and the printed circuit board 160 may be attached or bonded to the pad portion PAD. The plurality of pad electrodes PE of the pad portion PAD are electrically connected to one or more flexible circuit boards (or flexible films) CB, and various signals (or power) from the printed circuit board 160 and the flexible circuit boards (or flexible films) CB may be transmitted to the plurality of pixel driving circuits PD of the display region AA.

The flexible circuit board (or flexible film) CB may be a film in which various components are disposed on a flexible base film. For example, a driving integrated circuit (IC) such as a gate driver IC or a data driver IC may be disposed on the flexible circuit board (or flexible film) CB, but the embodiments of the present specification are not limited thereto. The driving IC may be a component which processes data and a driving signal for displaying an image. The driving IC may be disposed in a manner such as a chip on glass (COG), a chip on film (COF), a tape carrier package (TCP), or the like depending on a mounting manner, but the embodiments of the present specification are not limited thereto. The flexible circuit board (or flexible film) CB may be attached or bonded to the plurality of pad electrodes PE through a conductive adhesive layer, but the embodiments of the present specification are not limited thereto.

The printed circuit board 160 be a component which is electrically connected to one or more flexible circuit boards (or flexible films) CB and supplies a signal to the driving IC. The printed circuit board 160 may be disposed on one side of the flexible circuit board (or flexible film) CB and may be electrically connected to the flexible circuit board (or flexible film) CB. Various components for supplying various signals to the driving IC may be disposed on the printed circuit board 160. For example, various components such as a timing controller, a power supply, a memory, a processor, and the like may be disposed on the printed circuit board 160. For example, the printed circuit board 160 may include a power management integrated circuit PMIC, but the embodiments of the present specification are not limited thereto.

The printed circuit board 160 may include at least one hole 180, but the embodiments of the present specification are not limited thereto. An internal component which detects ambient light, temperature, or the like which may be provided to a plurality of sensors may be disposed in a region corresponding to at least one hole 180. For example, the internal component may include an ambient light sensor (ALS) or a temperature sensor, but the embodiments of the present specification are not limited thereto. For example, the hole 180 may be a transmission hole, but the embodiments of the present specification are not limited thereto.

The polarization layer 293 may be disposed on the display panel 100. The polarization layer 293 may prevent or reduce light generated from an external light source from entering the display panel 100 and affecting the light-emitting element or the like.

The cover member 120 may be disposed on the polarization layer 293. The cover member 120 may be a member for protecting the display panel 100. The second adhesive layer 295 may be disposed between the polarization layer 293 and the cover member 120. The cover member 120 may be attached to the display panel 100 by the second adhesive layer 295. The second adhesive layer 295 may include an optically clear adhesive (OCA), an optically clear resin (OCR), a pressure sensitive adhesive (PSA), or the like, but the embodiments of the present specification are not limited thereto.

The support substrate 110 may be disposed between the display panel 100 and the printed circuit board 160. The support substrate 110 may reinforce the rigidity of the display panel 100. The support substrate 110 may be a back plate, but the embodiments of the present specification are not limited thereto.

A plurality of link lines LL may be disposed in the non-display region NA. The plurality of link lines LL may be lines which transmit various signals from one or more flexible circuit boards (or flexible films) CB and the printed circuit board 160 to the display region AA. The plurality of link lines LL may extend from the plurality of pad electrodes PE of the second non-display region NA2 toward the bending region BA and the first non-display region NAI and may be electrically connected to a plurality of driving lines VL of the display region AA. The plurality of pixel driving circuits PD may be driven by receiving signals from one or more flexible circuit boards (or flexible films) CB and the printed circuit board 160 through the driving lines VL of the display region AA and the link lines LL of the non-display region NA.

For example, the plurality of driving lines VL may be lines for transmitting the signals output from the flexible circuit boards (or flexible films) CB and the printed circuit board 160 to the plurality of pixel driving circuits PD along with the plurality of link lines LL. The plurality of driving lines VL may be disposed in the display region AA and may be electrically connected to each of the plurality of pixel driving circuits PD. The plurality of driving lines VL may extend from the display region AA toward the non-display region NA and may be electrically connected to the plurality of link lines LL. Accordingly, the signals output from the flexible circuit boards (or flexible films) CB and the printed circuit board 160 may be respectively transmitted to the plurality of pixel driving circuits PD through the plurality of link lines LL and the plurality of driving lines VL.

As the bending region BA is bent, portions of the plurality of link lines LL may also be bent along with the bending region BA. Stress may be concentrated on the portions of the bent link lines LL, and accordingly, cracks may occur in the link lines LL. Accordingly, the plurality of link lines LL may be formed of a conductive material having excellent flexibility to reduce cracks when the bending region BA is bent. For example, the plurality of link lines LL may be formed of a conductive material having excellent flexibility such as gold (Au), silver (Ag), aluminum (Al), or the like, but the embodiments of the present specification are not limited thereto.

Further, the plurality of link lines LL may be formed of one of various conductive materials used in the display region AA. For example, the plurality of link lines LL may be formed of molybdenum (Mo), chromium (Cr), titanium (Ti), nickel Ni), neodymium (Nd), copper (Cu), and an alloy of silver (Ag) and magnesium (Mg), or an alloy thereof, but the embodiments of the present specification are not limited thereto. The plurality of link lines LL may be formed in a multi-layer structure including various conductive materials. For example, the plurality of link lines LL may be configured in a triple-layer structure of titanium (Ti)/aluminum (Al)/titanium (Ti), but the embodiments of the present specification are not limited thereto.

The plurality of link lines LL may be configured in various shapes to reduce stress. At least portions of the plurality of link lines LL disposed on the bending region BA may extend in the same direction as an extending direction of the bending region BA, or may extend in a different direction from the extending direction of the bending region BA to reduce stress. For example, when the bending region BA extends in one direction from the first non-display region NAI toward the second non-display region NA2, at least portions of the link lines LL disposed on the bending region BA may extend in a direction inclined to the one direction.

For another example, at least portions of the plurality of link lines LL may be configured in a pattern of various shapes. For example, at least portions of the plurality of link lines LL disposed on the bending region BA may have a shape in which a conductive pattern having at least one of a diamond shape, a rhombus shape, a trapezoidal wave shape, a triangular wave shape, a sawtooth wave shape, a sine wave shape, a circular shape, and an omega (Ω) shape is repeatedly disposed, but the embodiments of the present specification are not limited thereto. Accordingly, in order to minimize stress concentrated on the plurality of link lines LL and cracks according to the stress, the plurality of link lines LL may be formed in various shapes including the above-described shapes, but the embodiments of the present specification are not limited thereto.

Referring to FIGS. 2 and 3, the first non-display region NAI may include a border NAlb. The border NAlb of the first non-display region NAI may be a boundary region where the display panel is trimmed in the manufacturing process of the display panel. The border NAlb may be the outermost portion of the display. In the present specification, the border may be a boundary line disposed at the outermost side of a specific region.

The first non-display region NA1 may include a region where a trench T is disposed. The trench T may be disposed between the border NA1b of the first non-display region NA1 and a border of the display region AA. The region where the trench T is disposed may be formed to have substantially the same shape as the first non-display region NA1. For example, the first non-display region NA1 may have a rectangular shape whose four corners are formed in a round shape. In this case, the region where the trench T is disposed may have a rectangular shape whose four corners are formed in a round shape. An area of the rectangular shape formed by the outermost perimeter of the region where the trench T is disposed may be smaller than an area of the rectangular shape formed by the outermost perimeter of the first non-display region NA1. The region where the trench T is formed may be disposed to surround the plurality of pixels PX.

In one embodiment, the display region AA may include the region where the trench T is formed. The region in which the trench T is formed may be disposed to surround the plurality of pixels PX.

The trench T may be disposed between the display panel 100 and the bending region BA. The trench T may be disposed between at least a portion of the display panel 100 and the bending region BA.

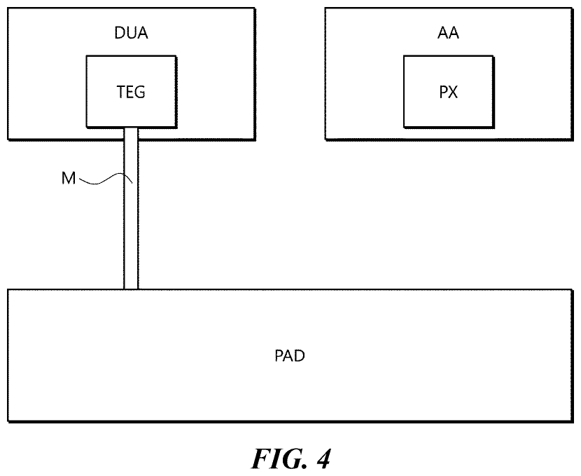

FIG. 4 is a block diagram showing a display panel according to the embodiment of the present specification.

Referring to FIG. 4, as described above, it is advantageous to perform an inspection every time a specific operation is performed in a manufacturing process to identify a cause of a problem and take additional measures before moving on to a next process for defects by in terms of yield of high-quality final products. Accordingly, the embodiment of the present specification may include a testing element group (TEG) structure TEG as a region including a plurality of dummy light-emitting elements, a third electrode, and a metal portion M. The TEG structure TEG may be a structure in a display panel designed to extract data to be measured.

In the present specification, in order to measure data for a second electrode which is disposed in the display region AA and supplies a cathode voltage (for example, a low potential power voltage) to the light-emitting element, the third electrode may be formed in a dummy region DUA to be substantially the same as or similar to the structure of the pixel PX disposed in the display region AA. For example, in order to measure various physical property values of the second electrode, a dummy light-emitting element, a first electrode, an optical layer, and the like conventionally disposed in the dummy region DUA may be utilized. Conventionally, for the purpose of manufacturing the dummy region DUA, an electrode which supplies the cathode voltage (for example, the low potential power voltage) onto the dummy light-emitting element was not separately disposed, and accordingly, the display region AA and the non-display region were distinguished. In the present specification, in order to acquire a measurement value substantially the same as or similar to the physical property values of the second electrode, the third electrode may be separately disposed on the dummy light-emitting element.

The physical property values may be correlated with factors, which may act as critical to quality (CTQ) in the operation process of the product, such as resistance of the electrode, roughness of the electrode, and the like. For pre-testing, monitoring, or the like of the CTQ, the dummy region DUA expected to have a high correlation with the pixel PX disposed in the display region AA may be utilized. For example, both the second electrode disposed in the display region AA and the third electrode disposed in the dummy region DUA may be disposed on an optical layer disorderly including the same metal particles. Accordingly, it may be assumed that the pixel PX disposed in the display region AA has a high correlation with the TEG structure TEG disposed in the dummy region DUA.

The TEG structure TEG may be electrically connected to the pad portion PAD in the display device according to the embodiment or a separate pad outside the display device. As described above, since the TEG structure TEG is designed to acquire physical property data values the same as/similar to the pixel PX in the display region AA, a separate device is required to measure and/or store the physical property values. The separate device may include the pad portion PAD in the display device. The separate device may include a separate pad outside the display device not found in a final product. The separate pad may be removed from the display device according to the embodiment during the manufacturing process or at a final operation of the manufacturing process.

The metal portion M may electrically connect the TEG structure TEG and the pad. The metal portion M may include various types of lines disposed in the display panel as described below. For example, the metal portion M may include a signal line TL, a first connection line 121, a second connection line 122, a third electrode CE3, and the like described below. In the final product, at least a portion of the metal portion M may be present in a removed state.

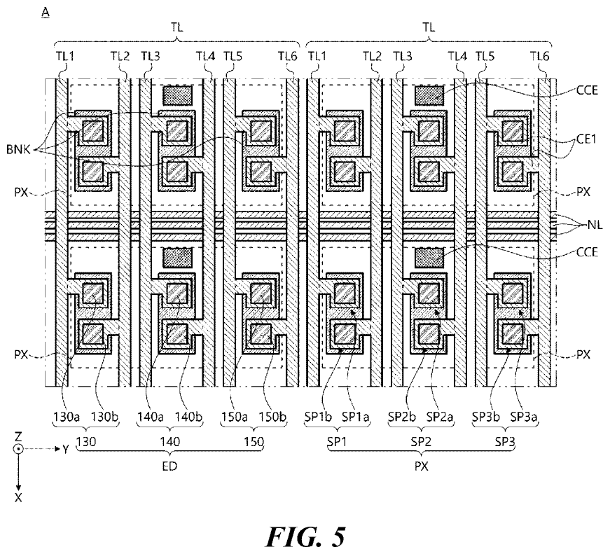

FIGS. 5 to 7 are plan views showing the display device according to the embodiment of the present specification.

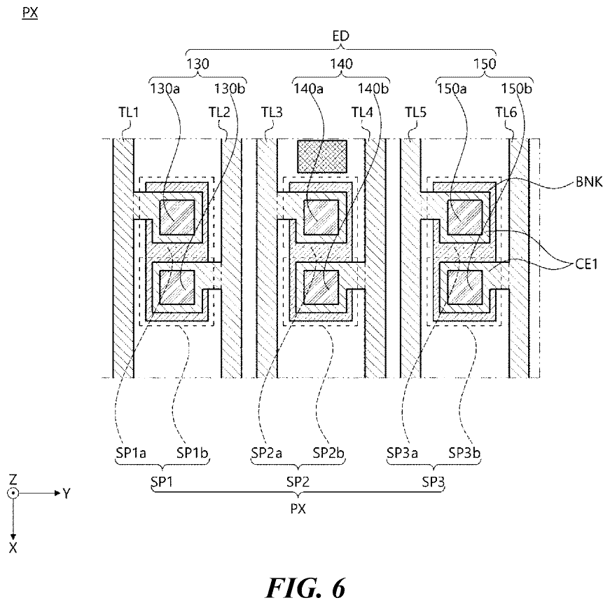

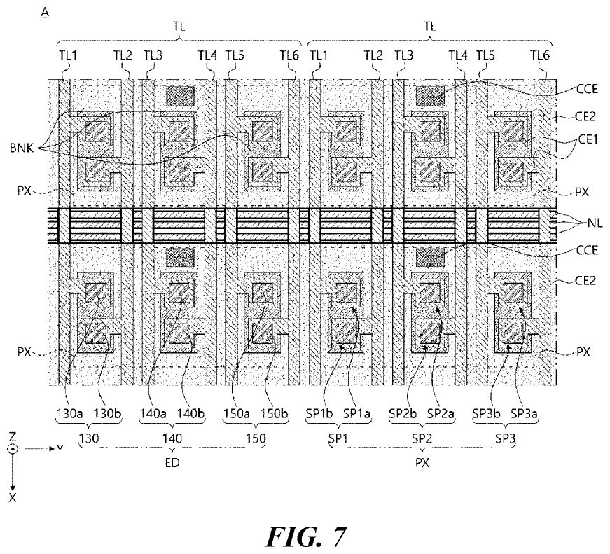

FIGS. 5 and 7 are partially enlarged views of portion A in FIG. 3. FIG. 6 is a partially enlarged view of one pixel PX.

In FIG. 5 and FIG. 6, only a plurality of signal lines TL, a plurality of communication lines NL, a plurality of first electrodes CE1, a plurality of banks BNK, and a plurality of light-emitting elements ED are shown, but the embodiments of the present specification are not limited thereto. FIG. 7 is an enlarged plan view in which a plurality of second electrodes CE2 are additionally disposed in FIG. 5.

Referring to FIGS. 5 to 7, a plurality of pixels PX, each composed of a plurality of subpixels may be disposed in the display region AA. Each of the plurality of subpixels includes a light-emitting element ED and may independently emit light. The plurality of subpixels may be disposed in a matrix form while forming a plurality of rows and a plurality of columns, but the embodiments of the present specification are not limited thereto.

The plurality of subpixels may include a first subpixel SP1, a second subpixel SP2, and a third subpixel SP3. For example, one of the first subpixel SP1, the second subpixel SP2, and the third subpixel SP3 may be a red subpixel, another may be a green subpixel, and the remaining may be a blue subpixel. The types of the plurality of subpixels are exemplary, and the embodiments of the present specification are not limited thereto.

Each of the plurality of pixels PX may include one or more first subpixels SP1, one or more second subpixels SP2, and one or more third subpixels SP3. For example, one pixel PX may include a pair of first subpixels SP1, a pair of second subpixels SP2, and a pair of third subpixels SP3. The pair of first subpixels SP1 may be composed of a 1-1 subpixel SP1a and a 1-2 subpixel SP1b. The pair of second subpixels SP2 may be composed of a 2-1 subpixel SP2a and a 2-2 subpixel SP2b. The pair of third subpixels SP3 may be composed of a 3-1 subpixel SP3a and a 3-2 subpixel SP3b. For example, one pixel PX may include the 1-1 subpixel SP1a and the 1-2 subpixel SP1b, the 2-1 subpixel SP2a and the 2-2 subpixel SP2b, and the 3-1 subpixel SP3a and the 3-2 subpixel SP3b, but the embodiments of the present specification are not limited thereto.

The plurality of subpixels forming one pixel PX may be disposed in various ways. For example, in one pixel PX, the pair of first subpixels SP1 may be disposed in the same column, the pair of second subpixels SP2 may be disposed in the same column, and the pair of third subpixels SP3 may be disposed in the same column. The first subpixel SP1, the second subpixel SP2, and the third subpixel SP3 may be disposed in the same row. The number and arrangement of the plurality of subpixels forming one pixel PX are exemplary, and the embodiments of the present specification are not limited thereto.

The plurality of signal lines TL may be disposed in regions between the plurality of subpixels. The plurality of signal lines TL may extend in a column direction between the plurality of subpixels. The plurality of signal lines TL may be lines which transmit an anode voltage from the pixel driving circuit PD to the plurality of subpixels. For example, the plurality of signal lines TL may be electrically connected to the plurality of pixel driving circuits PD and the first electrodes CE1 of the plurality of subpixels. The anode voltage output from the pixel driving circuit PD may be transmitted to the first electrodes CE1 of the plurality of subpixels through the plurality of signal lines TL. For example, the first electrode CE1 may be an electrode electrically connected to an anode electrode 134 of the light-emitting element ED. Accordingly, the anode voltage from the signal line TL may be transmitted to the anode electrode 134 of the light-emitting element ED through the first electrode CE1.

Accordingly, instead of forming a plurality of transistors and a plurality of storage capacitors for each of the plurality of subpixels, a structure of the display device 1000 may be simplified using a pixel driving circuit PD in which a plurality of pixel circuits are integrated. Further, as the circuits disposed in each of the plurality of subpixels are integrated into one pixel driving circuit PD, high efficiency and low power driving may be possible. The fact that the circuits disposed in each of the plurality of subpixels SP are integrated into one pixel driving circuit PD means that the plurality of pixel circuits capable of driving the plurality of light-emitting elements ED are included in the pixel driving circuit PD. The plurality of light-emitting elements ED may be driven by one pixel driving circuit PD in which the plurality of pixel circuits are integrated. For example, a 1-1 light-emitting element 130a, a 2-1 light-emitting element 140a, and a 3-1 light-emitting element 150a may be driven by one pixel driving circuit PD in which the plurality of pixel circuits are integrated.

The plurality of signal lines TL may include a first signal line TL1, a second signal line TL2, a third signal line TL3, a fourth signal line TL4, a fifth signal line TL5, and a sixth signal line TL6. Each of the first signal line TL1 and the second signal line TL2 may be electrically connected to each of the pair of first subpixels SP1. Each of the third signal line TL3 and the fourth signal line TL4 may be electrically connected to each of the pair of second subpixels SP2. Each of the fifth signal line TL5 and the sixth signal line TL6 may be electrically connected to each of the pair of third subpixels SP3.

The first signal line TL1 may be disposed on one side of the pair of first subpixels SP1, and the second signal line TL2 may be disposed on the other side of the pair of first subpixels SP1. The first signal line TL1 may be electrically connected to the first electrode CE1 of one first subpixel SP1 of the pair of first subpixels SP1, for example, the 1-1 subpixel SP1a. The second signal line TL2 may be electrically connected to the first electrode CE1 of the remaining first subpixel SP1 of the pair of first subpixels SP1, for example, the 1-2 subpixel SP1b.

The third signal line TL3 may be disposed on one side of the pair of second subpixels SP2, and the fourth signal line TL4 may be disposed on the other side of the pair of second subpixels SP2. For example, the third signal line TL3 may be disposed adjacent to the second signal line TL2. The third signal line TL3 may be electrically connected to the first electrode CE1 of one second subpixel SP2 of the pair of second subpixels SP2, for example, the 2-1 subpixel SP2a. The fourth signal line TL4 may be electrically connected to the first electrode CE1 of the remaining second subpixel SP2 of the pair of second subpixels SP2, for example, the 2-2 subpixel SP2b.

The fifth signal line TL5 may be disposed on one side of the pair of third subpixels SP3, and the sixth signal line TL6 may be disposed on the other side of the pair of third subpixels SP3. For example, the fifth signal line TL5 may be disposed adjacent to the fourth signal line TL4. The sixth signal line TL6 may be disposed adjacent to the first signal line TL1 connected to the neighboring pixel PX. The fifth signal line TL5 may be electrically connected to the first electrode CE1 of one third subpixel SP3 of the pair of third subpixels SP3, for example, the 3-1 subpixel SP3a. The sixth signal line TL6 may be electrically connected to the first electrode CE1 of the remaining third subpixel SP3 of the pair of third subpixels SP3, for example, the 3-2 subpixel SP3b.

The plurality of signal lines TL may be formed of a conductive material. For example, the plurality of signal lines TL may be formed of a conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), or the like, but the embodiments of the present specification are not limited thereto. For another example, the plurality of signal lines TL may be formed in a multi-layer structure of the conductive material. For example, the plurality of signal lines TL may be formed in a multi-layer structure of titanium (Ti)/aluminum (Al)/titanium (Ti)/indium tin oxide (ITO), but the embodiments of the present specification are not limited thereto.

The plurality of communication lines NL may be disposed in regions between the plurality of pixels PX. The plurality of communication lines NL may be disposed to extend in a row direction in the regions between the plurality of pixels PX. The plurality of communication lines NL may be disposed in regions between the plurality of second electrodes CE2 and may not overlap the plurality of second electrodes CE2. For example, the plurality of communication lines NL may be lines used for short-range communication such as near field communication (NFC). The plurality of communication lines NL may function as antennas. For example, the plurality of communication lines NL may be a plurality of connection lines, and the like, but the embodiments of the present specification are not limited thereto.

According to the present specification, a bank BNK may be disposed on each of the plurality of subpixels. The plurality of banks BNK may be structures on which the plurality of light-emitting elements ED are mounted. The plurality of banks BNK may guide positions of the plurality of light-emitting elements ED in a transfer process of transferring the plurality of light-emitting elements ED to the display device 1000. In the transfer process of the plurality of light-emitting elements ED, the plurality of light-emitting elements ED may be transferred onto the plurality of banks BNK. The plurality of banks BNK may be bank patterns, structures, or the like, but the embodiments of the present specification are not limited thereto.

A bank BNK of the first subpixel SP1, a bank BNK of the second subpixel SP2, and a bank BNK of the third subpixel SP3 may disposed spaced apart from each other. The bank BNK of the first subpixel SP1, the bank BNK of the second subpixel SP2, and the bank BNK of the third subpixel SP3 may be configured to be separated. Accordingly, the banks BNK of the first subpixel SP1, the second subpixel SP2, and the third subpixel SP3 to which different types of light-emitting elements ED are transferred may be easily identified.

A bank BNK of the 1-1 subpixel SP1a and a bank BNK of the 1-2 subpixel SP1b may be connected to each other, or may be formed to be spaced apart or separated from each other. For example, in consideration of the design of the transfer process requirements or the like, the bank BNK of the 1-1 subpixel SP1a and the bank BNK of the 1-2 subpixel SP1b where the same type of light-emitting elements ED are disposed may be connected to each other or may be spaced apart or separated from each other. Further, a bank BNK of the 2-1 subpixel SP2a and a bank BNK of the 2-2 subpixel SP2b may be connected to each other, or may be formed to be spaced apart or separated from each other. A bank BNK of the 3-1 subpixel SP3a and a bank BNK of the 3-2 subpixel SP3b may be connected to each other, or may be formed to be spaced apart or separated from each other. Accordingly, the banks of the pair of first subpixels SP1, the banks BNK of the pair of second subpixels SP2, and the banks BNK of the pair of third subpixels SP3 may be formed in various ways, and the embodiments of the present specification are not limited thereto.

For example, the plurality of banks BNK may be formed of an organic insulating material. The plurality of banks BNK may be formed of a single layer or multi-layers made of organic insulating material. For example, the plurality of banks BNK may be formed of photoresist, polyimide (PI), an acryl-based material, or the like, but the embodiments of the present specification are not limited thereto.

The first electrode CE1 may be disposed on each of the plurality of subpixels. The first electrode CE1 may be disposed on the bank BNK. The first electrode CE1 may be electrically connected to one signal line TL of the plurality of signal lines TL. At least a portion of the first electrode CE1 may extend outside the bank BNK and may be electrically connected to the signal line TL most adjacent to the first electrode CE1.

For example, a portion of the first electrode CE1 of the 1-1 subpixel SP1a may extend to one side region of the 1-1 subpixel SP1a and may be electrically connected to the first signal line TL1, and a portion of the first electrode CE1 of the 1-2 subpixel SP1b may extend to the other side region of the 1-2 subpixel SP1b and may be electrically connected to the second signal line TL2. A portion of the first electrode CE1 of the 2-1 subpixel SP2a may extend to one side region of the 2-1 subpixel SP2a and may be electrically connected to the third signal line TL3, and a portion of the first electrode CE1 of the 2-2 subpixel SP2b may extend to the other side region of the 2-2 subpixel SP2b and may be electrically connected to the fourth signal line TL4. A portion of the first electrode CE1 of the 3-1 subpixel SP3a may extend to one side region of the 3-1 subpixel SP3a and may be electrically connected to the fifth signal line TL5, and a portion of the first electrode CE1 of the 3-2 subpixel SP3b may extend to the other side region of the 3-2 subpixel SP3b and may be electrically connected to the sixth signal line TL6.

The first electrode CE1 may be electrically connected to the anode electrode 134 of the light-emitting element ED and may transmit the anode voltage from the pixel driving circuit PD to the light-emitting element ED through the signal line TL. Different voltages may be applied to the first electrode CE1 of each of the plurality of subpixels depending on the image to be displayed. For example, different voltages may be applied to the first electrode CE1 of each of the plurality of subpixels. Accordingly, the first electrode CE1 may be a pixel electrode, and the embodiments of the present specification are not limited thereto.

The first electrode CE1 may be formed of a conductive material. For example, the first electrode CE1 may be integrally configured with the plurality of signal lines TL. For example, the first electrode CE1 may be formed of the same conductive material as the plurality of signal lines TL, but the embodiments of the present specification are not limited thereto. For example, the first electrode CE1 may be formed of a conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), or the like, but the embodiments of the present specification are not limited thereto. For another example, the first electrode CE1 may be formed in a multi-layer structure made of the conductive material. For example, the plurality of first electrodes CE1 may be formed in a multi-layer structure of titanium (Ti)/aluminum (Al)/titanium (Ti)/indium tin oxide (ITO), but the embodiments of the present specification are not limited thereto.

The light-emitting element ED may be disposed in each of the plurality of subpixels. The plurality of light-emitting elements ED may be any one of an LED and a micro LED, but the embodiments of the present specification are not limited thereto. The plurality of light-emitting elements ED may be disposed on the bank BNK and the first electrode CE1. The plurality of light-emitting elements ED may be disposed on the first electrode CE1 and may be electrically connected to the first electrode CE1. Accordingly, the light-emitting element ED may emit light by receiving the anode voltage from the pixel driving circuit PD through the signal line TL and the first electrode CE1.

The plurality of light-emitting elements ED may include a first light-emitting element 130, a second light-emitting element 140, and a third light-emitting element 150. The first light-emitting element 130 may be disposed in the first subpixel SP1. The second light-emitting element 140 may be disposed in the second subpixel SP2. The third light-emitting element 150 may be disposed in the third subpixel SP3. For example, one of the first light-emitting element 130, the second light-emitting element 140, and the third light-emitting element 150 may be a red light-emitting element, another may be a green light-emitting element, and the remaining may be a blue light-emitting element, but the embodiments of the present specification are not limited thereto. Accordingly, various colors of light including white may be implemented by combining red light, green light, and blue light emitted from the plurality of light-emitting elements ED. The types of the plurality of light-emitting elements ED are exemplary, and the embodiments of the present specification are not limited thereto.

The first light-emitting element 130 may include a 1-1 light-emitting element 130a disposed in the 1-1 subpixel SP1a and a 1-2 light-emitting element 130b disposed in the 1-2 subpixel SP1b. The second light-emitting element 140 may include a 2-1 light-emitting element 140a disposed in the 2-1 subpixel SP2a and a 2-2 light-emitting element 140b disposed in the 2-2 subpixel SP2b. The third light-emitting element 150 may include a 3-1 light-emitting element 150a disposed in the 3-1 subpixel SP3a and a 3-2 light-emitting element 150b disposed in the 3-2 subpixel SP3b.

A second electrode CE2 may be disposed in each of the plurality of subpixels. The second electrode CE2 may be disposed on the light-emitting element ED. The second electrode CE2 may be electrically connected to the pixel driving circuit PD through a plurality of contact electrodes CCE.

For example, the second electrode CE2 may be electrically connected to the cathode electrode 135 of the light-emitting element ED to transmit the cathode voltage from the pixel driving circuit PD to the light-emitting element ED. The same cathode voltage may be applied to the second electrode CE2 of each of the plurality of subpixels. For example, the same voltage may be applied to the second electrode CE2 of each of the plurality of subpixels and the cathode electrode 135 of the light-emitting element ED. Accordingly, the second electrode CE2 may be a common electrode, but the embodiments of the present specification are not limited thereto.

At least some of the plurality of subpixels may share the second electrode CE2. At least some of the second electrodes CE2 of each of the plurality of subpixels may be electrically connected to each other. As the same voltage is applied to the second electrode CE2, the second electrodes CE2 of at least some of the subpixels may be shared and used. For example, the second electrodes CE2 of at least some pixels PX of the plurality of pixels PX disposed in the same row may be connected to each other. For example, one second electrode CE2 may be disposed in the plurality of pixels PX. One second electrode CE2 may be disposed for each n subpixel.

For example, some of the second electrodes CE2 of each of the plurality of subpixels may be disposed to be spaced apart or separated from each other. For example, the second electrode CE2 connected to pixels PX in an nth row and the second electrode CE2 connected to pixels PX in an n+1th row may be disposed to be spaced apart or separated from each other. For example, the plurality of second electrodes CE2 may be disposed spaced apart from each other with the plurality of communication lines NL extending in the row direction therebetween. Accordingly, the number of the plurality of subpixels may be greater than the number of the plurality of second electrodes CE2. For other examples, all the second electrodes CE2 of the plurality of subpixels may be connected to each other and thus only one second electrode CE2 may be disposed on the substrate 110, and the embodiments of the present specification are not limited thereto.

The plurality of second electrodes CE2 may be formed of a transparent conductive material, but the embodiments of the present specification are not limited thereto. The plurality of second electrodes CE2 may be formed of a transparent conductive material so that light emitted from the light-emitting element ED may be directed toward an upper portion of the second electrodes CE2. For example, the second electrode CE2 may be formed of a transparent conductive material such as indium tin oxide (ITO), indium zinc oxide (IZO), indium gallium zinc oxide (IGZO), or the like, but the embodiments of the present specification are not limited thereto.

The plurality of contact electrodes CCE may be disposed on the substrate 110. For example, the plurality of contact electrodes CCE may be disposed spaced apart from the plurality of banks BNK and the plurality of signal lines TL. Each of the plurality of second electrodes CE2 may overlap at least one contact electrode CCE. For example, one second electrode CE2 may overlap the plurality of contact electrodes CCE.

For example, the plurality of contact electrodes CCE may be electrically connected to the plurality of second electrodes CE2. The plurality of contact electrodes CCE may be disposed between the substrate 110 and the plurality of second electrodes CE2 to transmit the cathode voltage from the pixel driving circuit PD to the second electrodes CE2.

For example, when micro LEDs are used as the light-emitting elements ED, the display device 1000 may be manufactured by forming a plurality of micro LEDs on a wafer and transferring the micro LEDs to the substrate 110 of the display device 1000. In the process of transferring the plurality of light-emitting elements ED having a fine size from the wafer to the substrate 110, various defects may occur. For example, in some subpixels, a non-transfer defect in which the light-emitting element ED is not transferred may occur, and in other subpixels, a defect in which the light-emitting element ED is transferred out of a right position due to an alignment error may occur. Further, although the transfer process is normally performed, the transferred light-emitting element ED itself may be defective. Accordingly, in consideration of defects during the transfer process of the plurality of light-emitting elements ED, the plurality of light-emitting elements ED of the same type may be transferred to one subpixel. A lighting test of the plurality of light-emitting elements ED is performed, and only one light-emitting element ED that is finally determined to be normal may be used.

For example, the 1-1 light-emitting element 130a and the 1-2 light-emitting element 130b may be transferred together to one pixel PX and whether there are defects may be inspected. When both the 1-1 light-emitting element 130a and the 1-2 light-emitting element 130b are determined to be normal, only the 1-1 light-emitting element 130a may be used and the 1-2 light-emitting element 130b may not be used. For another example, when only the 1-2 light-emitting element 130b is determined to be normal among the 1-1 light-emitting element 130a and the 1-2 light-emitting element 130b, the 1-1 light-emitting element 130a may not be used and only the 1-2 light-emitting element 130b may be used. Accordingly, even when the plurality of light-emitting elements ED of the same type are transferred to one pixel PX, only one light-emitting element ED may be finally used.

Accordingly, one of the pair of light-emitting elements ED may be a main (or primary) light-emitting element ED and the other may be a redundancy light-emitting element ED. The redundancy light-emitting element ED may be a spare light-emitting element ED transferred to prepare for a defect of the main light-emitting element ED. When the main light-emitting element ED is defective, the redundancy light-emitting element ED may be used as a replacement. Accordingly, the deterioration of display quality due to the defects of the main light-emitting element ED and the redundancy light-emitting element ED may be minimized by transferring the main light-emitting element ED and the redundancy light-emitting element ED together to one pixel PX.

For example, the 1-1 light-emitting element 130a, the 2-1 light-emitting element 140a, and the 3-1 light-emitting element 150a transferred to one pixel PX may be used as the main light-emitting elements ED, and the 1-2 light-emitting element 130b, the 2-2 light-emitting element 140b, and the 3-2 light-emitting element 150b may be used as the redundancy light-emitting elements ED.

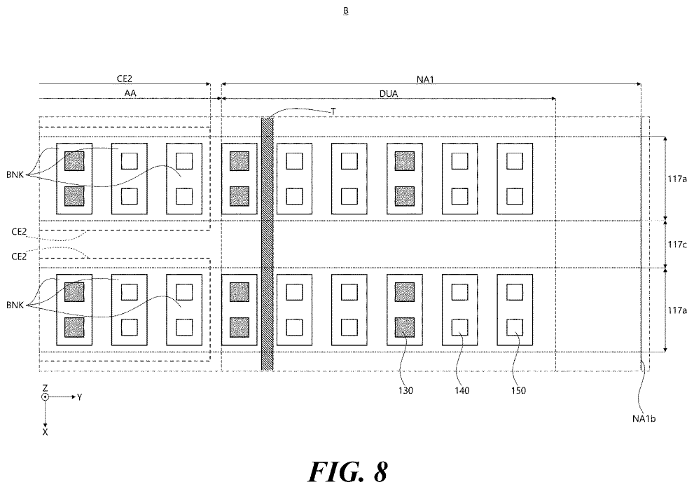

FIGS. 8 to 10 are plan views showing the display device according to the embodiment of the present specification. Configurations having substantially the same functions between the embodiments are denoted by the same reference numerals, and repeated descriptions thereof will be omitted.

FIG. 8 is a partially enlarged view showing portion B in FIG. 3.

Referring to FIG. 8, the display device according to the embodiment of the present specification may include a display region AA and a first non-display region NA1. The display region AA may include a plurality of light-emitting elements 130, 140, and 150, a second electrode CE2, a first optical layer 117a, and a third optical layer 117c. The first non-display region NA1 may include the plurality of light-emitting elements 130, 140, and 150, the first optical layer 117a, and the third optical layer 117c. A third electrode is not shown.

The plurality of light-emitting elements 130, 140, and 150 disposed in the display region AA may emit light by a high potential power voltage applied to a first electrode as the plurality of second electrodes CE2 are disposed. The second electrodes CE2 may be formed to entirely cover a plurality of pixels to be common to the plurality of pixels. The second electrodes CE2 may be formed to be common only to the plurality of light-emitting elements 130, 140, and 150 disposed on each pixel.

The plurality of light-emitting elements 130, 140, and 150 disposed in the display region AA and the first non-display region NA1 may include a first light-emitting element 130, a second light-emitting element 140, and a third light-emitting element 150. The first light-emitting element 130, the second light-emitting element 140, and the third light-emitting element 150 may respectively implement a first color, a second color, and a third color. The first to third colors may be any one of red, green, and blue selected so as not to overlap each other, but the embodiment of the present specification is not limited thereto. For example, the first color may be red, the second color may be green, and the third color may be blue, but the present specification is not limited thereto.

The first non-display region NA1 may include a dummy region DUA. The dummy region DUA may include a dummy pixel including a plurality of dummy light-emitting elements. The second electrode CE2 may not be disposed in the first non-display region NA1 where the plurality of dummy light-emitting elements are disposed. Accordingly, even when the high potential power voltage is applied to the first electrode disposed on the dummy light-emitting elements, the dummy light-emitting elements may not emit light.

A trench T may be disposed between the plurality of light-emitting elements 130, 140, and 150. The trench T may be disposed to extend in a first direction (for example, an X-axis direction). The trench T may be disposed between the first light-emitting element 130 and the second light-emitting element 140, but is not limited thereto. As the trench T is disposed, the display panel 100 may be protected from moisture permeation from the outside. For example, since effects such as prevention of moisture permeation and the like can be implemented, the reliability of the display device may be enhanced.

One pixel may include the first light-emitting element 130, the second light-emitting element 140, and the third light-emitting element 150. The third optical layer 117c may be disposed between the plurality of pixels disposed in the first direction (for example, the X-axis direction). For example, the third optical layer 117c may be disposed to extend in a second direction (for example, a Y-axis direction) intersecting the first direction.

The first optical layer 117a may be disposed to overlap a region where the pixels or dummy pixels are disposed in a planar direction (for example, in the Z-axis direction) of the display panel 100. The third optical layer 117c may be disposed between a plurality of first optical layers 117a (for example, in the X-axis direction). In one embodiment, the first optical layer 117a may extend to one end (or one side) of the display panel.

A passivation layer 116 may be disposed on the first optical layer 117a. The passivation layer 116 may be formed on at least portions of the display region AA and the first non-display region NA1. The passivation layer 116 may be formed on the first optical layer 117a to cover the display region AA and the first non-display region NA1. For example, the passivation layer 116 may be formed on the first optical layer 117a to entirely cover the display region AA and the first non-display region NA1. For example, the passivation layer 116 may be disposed in the entire display region AA and first non-display region NA1. Since the display device according to the embodiment of the present specification includes the passivation layer 116 and the trench T, moisture permeation from the outside of the display device is prevented and thus the lifespan of the display device may be enhanced. Accordingly, a display device which may reduce power consumption and may be driven at low power may be provided.

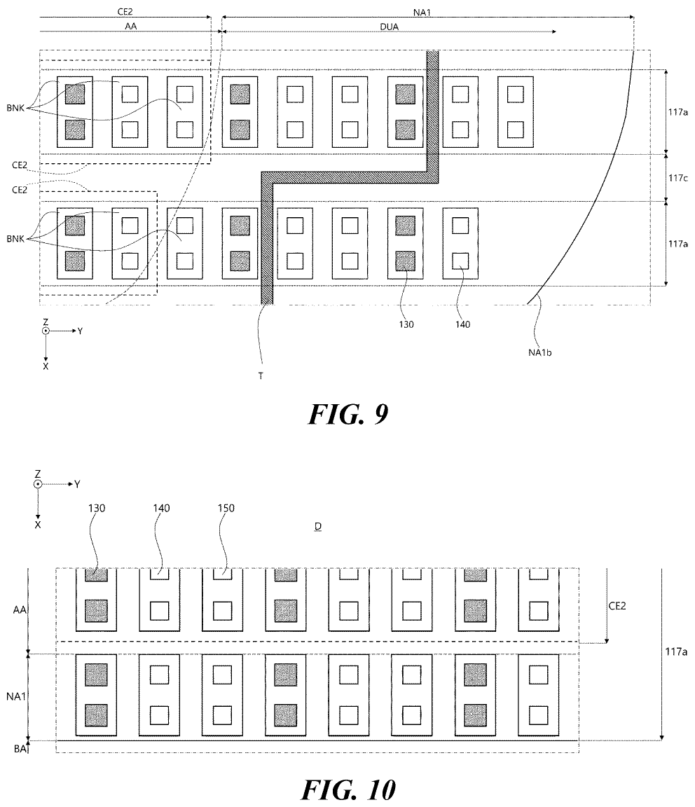

FIG. 9 is a partially enlarged view showing portion C in FIG. 3.

Referring to FIG. 9, the display device may include rounded edges, but the embodiment of the present specification is not limited thereto. The trench T may include a portion disposed to extend in the first direction and a portion disposed to extend in the second direction intersecting the first direction. As shown, the first direction and the second direction intersect each other at a vertical angle in the X-axis direction and the Y-axis direction, but a direction in which the trench T is disposed to extend is not limited thereto. For example, a disposition angle of the trench may be arbitrarily set or adjusted.

FIG. 10 is a partially enlarged view showing portion D in FIG. 3.

Referring to FIG. 10, the display device may include the display region AA and the first non-display region NA1. The display device may include the first non-display region NA1 disposed between the bending region BA and the display region AA. The first non-display region NA1 may include a trench (not shown). The trench may block permeation of moisture particles in a direction in which the bending region BA is disposed. Accordingly, the operation reliability of the display device is enhanced, and thus the lifespan may extend.

A passivation layer may be disposed in the entire display region AA and first non-display region NA1. Since the display device according to the embodiment of the present specification includes the passivation layer and the trench, the moisture permeation from the outside of the display device is prevented and thus the lifespan of the display device may be enhanced. Accordingly, power consumption may be reduced and low-power driving may be performed in the long term.

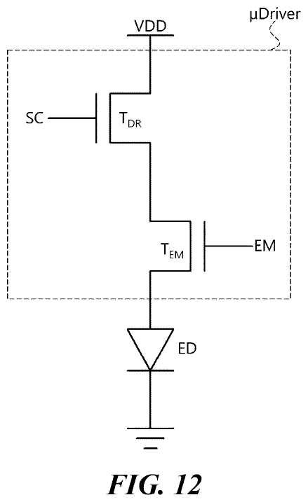

FIG. 12 is a view showing a circuit structure according to the embodiment of the present specification.

In FIG. 12, an example in which one light-emitting element ED is connected to a micro driver μDriver is described, but is not limited thereto. For example, eight light-emitting elements ED may be connected to one micro driver μDriver. For another example, 16 light-emitting elements ED may be connected to one micro driver μDriver, or 32 light-emitting elements ED or 64 light-emitting elements ED may be simultaneously connected to one micro driver μDriver. The light-emitting element ED may be a micro light-emitting element μLED.

One micro driver μDriver may include a driving transistor TDR and a light-emitting transistor TEM, but the embodiments of the present specification are not limited thereto.

For example, in the driving transistor T_{DR}, a high potential power voltage VDD may be applied to a first electrode, a first electrode of the light-emitting transistor T_{EM} may be connected to a second electrode, and a scan signal SC may be applied to a gate electrode. The scan signal SC applied to the gate electrode of the driving transistor T_{DR} is a direct current power source, and a fixed reference voltage Vref may be applied for each frame, but the embodiments of the present specification are not limited thereto.

In the light-emitting transistor T_{EM}, the second electrode of the driving transistor T_{DR} may be connected to the first electrode, the light-emitting element ED may be connected to a second electrode, and a light-emitting signal EM may be applied to a gate electrode. The light-emitting signal EM applied to the gate electrode of the light-emitting transistor T_{EM} may be a pulse width modulation signal which varies for each frame, but the embodiments of the present specification are not limited thereto.

A first electrode of the light-emitting element ED may be connected to the second electrode of the light-emitting transistor T_{EM}, and a second electrode of the light-emitting element ED may be connected to the ground. For example, the first electrode of the light-emitting element ED may be an anode electrode and the second electrode of the light-emitting element ED may be a cathode electrode, but the embodiments of the present specification are not limited thereto.

The driving transistor T_{DR} and the light-emitting transistor T_{EM} may each be an n-type transistor or a p-type transistor.

In the micro driver μDriver, the driving transistor T_{DR} may be turned on by the scan signal SC applied from a timing controller T-CON, and the light-emitting transistor T_{EM} may be turned on by the light-emitting signal EM. Accordingly, as a driving current is applied to the light-emitting element ED via the driving transistor T_{DR} and the light-emitting transistor T_{EM} by a high potential power voltage VDD applied to the first electrode of the driving transistor T_{DR}, the light-emitting element ED may emit light.

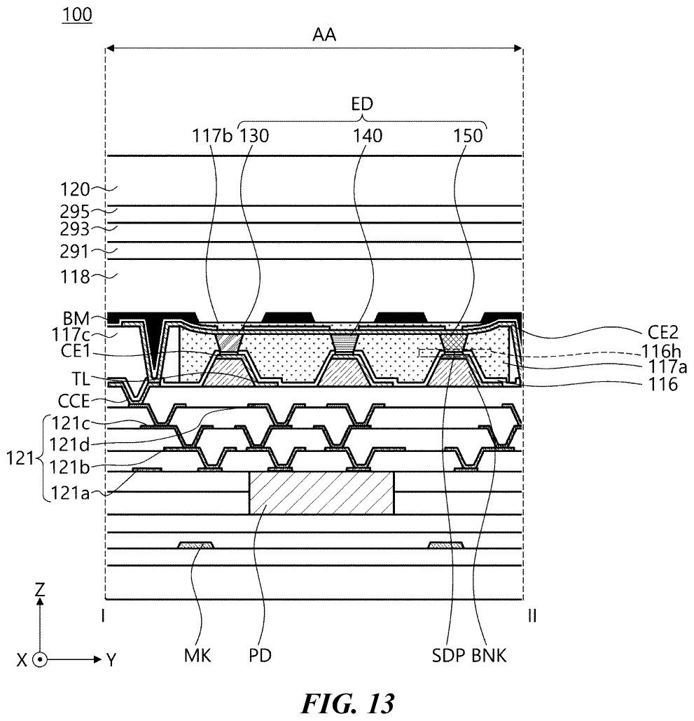

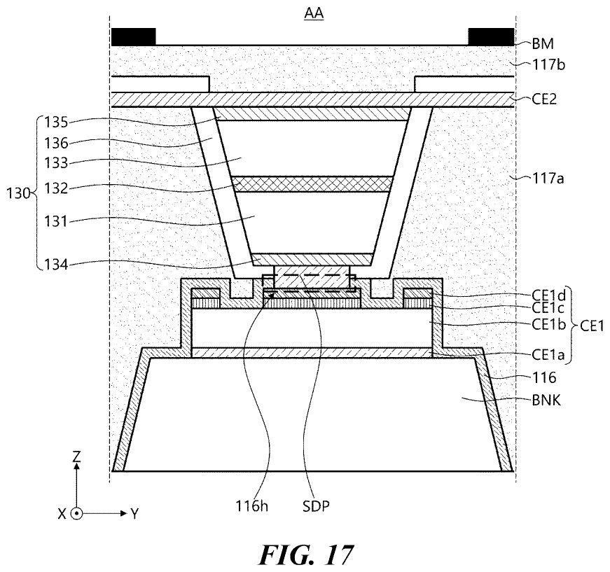

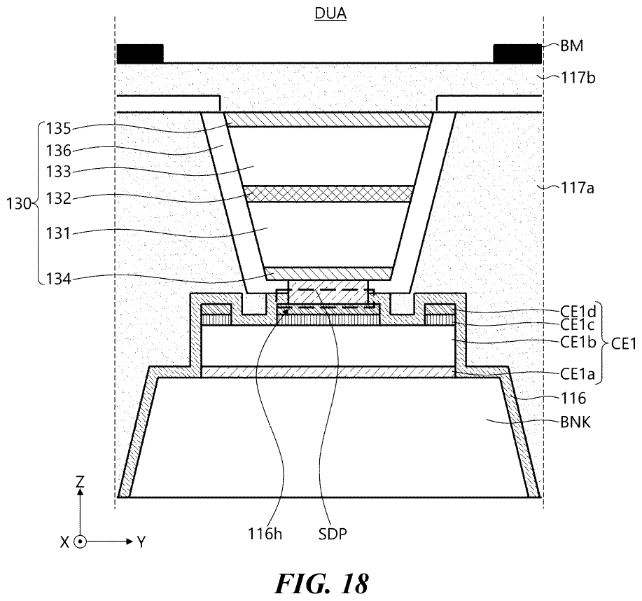

FIGS. 13 to 16 are cross-sectional views showing the display device according to the embodiment of the present specification. FIG. 17 is a cross-sectional view showing the display device according to the embodiment of the present specification. FIG. 18 is a cross-sectional view showing the display device according to the embodiment of the present specification.

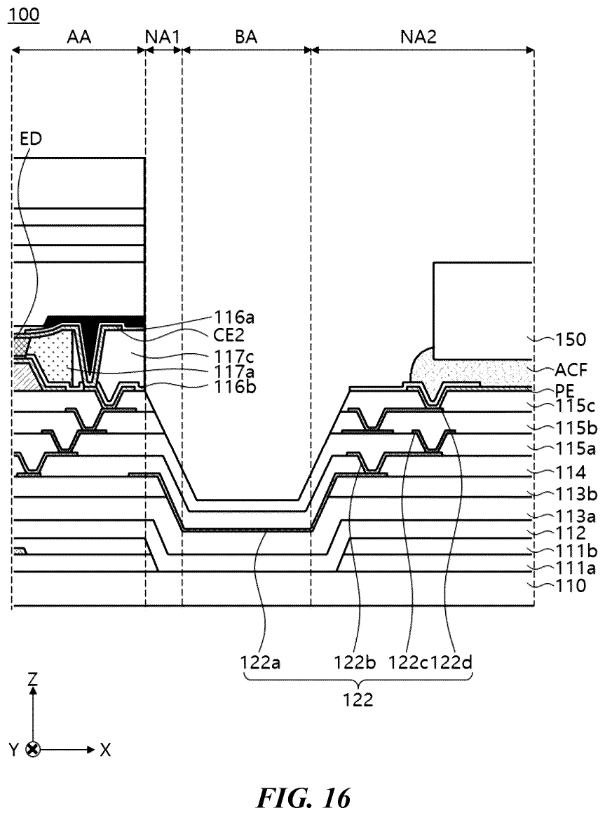

FIG. 13 is a cross-sectional view of the display region AA taken along line I-II in FIG. 11. FIG. 16 is a cross-sectional view of the display region AA, the first non-display region NA1, the bending region BA, and the second non-display region NA2 taken along line III-IV in FIG. 11.

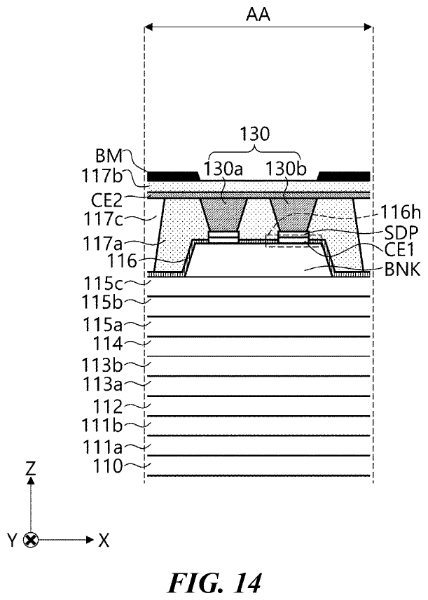

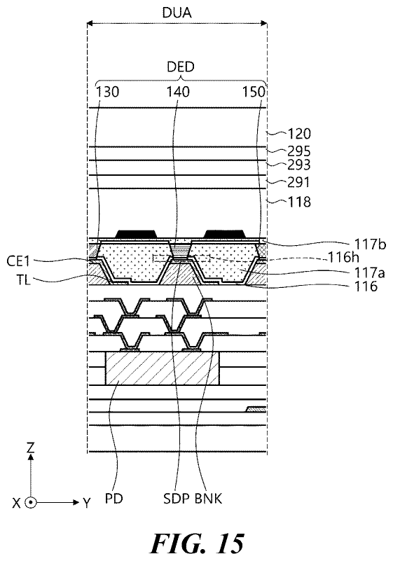

FIGS. 13 and 14 are cross-sectional views of the display region according to the embodiment of the present specification. FIG. 15 is a cross-sectional view of the non-display region according to the embodiment of the present specification. Configurations having substantially the same functions between the cross-sectional views are denoted by the same reference numerals, and repeated descriptions thereof will be omitted. Each drawing shows different coordinate axes according to a cutting direction.

Referring to FIGS. 13 to 16, a first buffer layer 111a and a second buffer layer 111b may be disposed in the remaining region of a substrate 110 excluding the bending region BA.

The first buffer layer 111a and the second buffer layer 111b may be disposed in the display region AA, the first non-display region NA1, and the second non-display region NA2. The first buffer layer 111a and the second buffer layer 111b may reduce permeation of moisture or impurities through the substrate 110. The first buffer layer 111a and the second buffer layer 111b may be formed of an inorganic insulating material. For example, the first buffer layer 111a and the second buffer layer 111b may be formed of a single layer or multi-layers made of silicon oxide (SiOₓ) or silicon nitride (SiNₓ), but the embodiments of the present specification are not limited thereto.

For example, portions of the first buffer layer 111a and the second buffer layer 111b in the bending region BA may be removed. An upper surface of the substrate 110 located in the bending region BA may be exposed from the first buffer layer 111a and the second buffer layer 111b. Cracks of the first buffer layer 111a and the second buffer layer 111b which may occur during bending may be minimized by removing the first buffer layer 111a and the second buffer layer 111b formed of an inorganic insulating material from the bending region BA.

A plurality of alignment keys MK may be disposed between the first buffer layer 111a and the second buffer layer 111b. The plurality of alignment keys MK may be configured to identify a position of the pixel driving circuit PD during a manufacturing process of the display device 1000. For example, the plurality of alignment keys MK may be configured to align the position of the pixel driving circuit PD transferred onto an adhesive layer 112. For another example, the plurality of alignment keys MK may be omitted.

The adhesive layer 112 may be disposed on the second buffer layer 111b. The adhesive layer 112 may be disposed in the display region AA, the first non-display region NA1, the bending region BA, and the second non-display region NA2. For another example, at least a portion of the adhesive layer 112 may be removed in the non-display region NA including the bending region BA. For example, the adhesive layer 112 may be formed of any one of an adhesive polymer, an epoxy resin, a UV-curable resin, a polyimide series, an acrylate series, a urethane series, and polydimethylsiloxane (PDMS), but the embodiments of the present specification are not limited thereto.

The pixel driving circuit PD may be disposed on the adhesive layer 112 in the display region AA. When the pixel driving circuit PD is implemented as a driving driver, the driving driver may be mounted on the adhesive layer 112 by the transfer process, but the embodiments of the present specification are not limited thereto.

A first protective layer 113a and a second protective layer 113b may be disposed on the adhesive layer 112 and the pixel driving circuit PD. The first protective layer 113a and the second protective layer 113b may be disposed to surround the sides of the pixel driving circuit (PD), but the embodiments of the present specification are not limited thereto. For example, the second protective layer 113b may be disposed to cover at least a portion of an upper surface of the pixel driving circuit PD. For example, at least one of the first protective layer 113a and the second protective layer 113b disposed in the bending region BA may be omitted. For example, the first protective layer 113a may be entirely disposed in the display region AA and the non-display region NA, and the second protective layer 113b may be partially disposed in the display region AA, the first non-display region NA1, and the second non-display region NA2. For example, a portion of the second protective layer 113b in the bending region BA may be removed. However, the embodiments of the present specification are not limited thereto.

The first protective layer 113a and the second protective layer 113b may be formed of an organic insulating material, but the embodiments of the present specification are not limited thereto. For example, the first protective layer 113a and the second protective layer 113b may be formed of photoresist, polyimide (PI), a photo acrylic material, or the like, but the embodiments of the present specification are not limited thereto. For example, the first protective layer 113a and the second protective layer 113b may be overcoating layers or insulating layers, but the embodiments of the present specification are not limited thereto.

According to the present specification, a plurality of first connection lines 121 may be disposed on the second protective layer 113b in the display region AA. The plurality of first connection lines 121 may be lines for electrically connecting the pixel driving circuit PD to other components. For example, the pixel driving circuit PD may be electrically connected to the plurality of signal lines TL, the plurality of contact electrodes CCE, and the like through the plurality of first connection lines 121. For example, the plurality of first connection lines 121 may include a 1-1 connection line 121a, a 1-2 connection line 121b, a 1-3 connection line 121c, and a 1-4 connection line 121d, but the embodiments of the present specification are not limited thereto.

For example, a plurality of 1-1 connection lines 121a may be disposed on the second protective layer 113b. The plurality of 1-1 connection lines 121a may be electrically connected to the pixel driving circuit PD. The plurality of 1-1 connection lines 121a may transmit a voltage output from the pixel driving circuit PD to the first electrode CE1 or the second electrode CE2.

For example, a third protective layer 114 may be disposed on the second protective layer 113b. The third protective layer 114 may be entirely disposed in the display region AA and the non-display region NA. The third protective layer 114 may cover a side surface of the second protective layer 113b and an upper surface of the first protective layer 113a in the bending region BA. The third protective layer 114 may be formed of an organic insulating material. For example, the third protective layer 114 may be formed of photoresist, polyimide (PI), a photo acrylic material, or the like, but the embodiments of the present specification are not limited thereto. For example, the first protective layer 113a, the second protective layer 113b, and the third protective layer 114 may be formed of the same material, but the embodiments of the present specification are not limited thereto.

A plurality of 1-2 connection lines 121b may be disposed on the third protective layer 114. The plurality of 1-2 connection lines 121b may be connected to or directly connected to the pixel driving circuit PD. For example, some of the 1-2 connection lines 121b may be directly connected to the pixel driving circuit PD through a contact hole of the third protective layer 114. Other 1-2 connection lines 121b may be electrically connected to the 1-1 connection line 121a through a contact hole of the third protective layer 114. However, the embodiments of the present specification are not limited thereto. The voltage output from the pixel driving circuit PD may be transmitted to the first electrode CE1 or the second electrode CE2 through the plurality of 1-2 connection lines 121b and other connection lines.

A first insulating layer 115a may be disposed on the plurality of 1-2 connection lines 121b. The first insulating layer 115a may be entirely disposed in the display region AA and the non-display region NA, but the embodiments of the present specification are not limited thereto. The first insulating layer 115a may be formed of an organic insulating material, but the embodiments of the present specification are not limited thereto. For example, the first insulating layer 115a may be formed of photoresist, polyimide (PI), a photo acrylic material, or the like, but the embodiments of the present specification are not limited thereto.

A plurality of 1-3 connection lines 121c may be disposed on the first insulating layer 115a. The plurality of 1-3 connection lines 121c may be electrically connected to the plurality of 1-2 connection lines 121b. For example, the 1-3 connection lines 121c may be electrically connected to the 1-2 connection lines 121b through contact holes of the first insulating layer 115a.

A second insulating layer 115b may be disposed on the plurality of 1-3 connection lines 121c. The second insulating layer 115b may be disposed in the remaining region excluding the bending region BA, but the embodiments of the present specification are not limited thereto. The second insulating layer 115b may be disposed in the display region AA, the first non-display region NA1, and the second non-display region NA2, but the embodiments of the present specification are not limited thereto. For example, a portion of the second insulating layer 115b disposed in the bending region BA may be removed. The second insulating layer 115b may be formed of an organic insulating material, but the embodiments of the present specification are not limited thereto. For example, the second insulating layer 115b may be formed of photoresist, polyimide (PI), a photo acrylic material, or the like, but the embodiments of the present specification are not limited thereto.

A plurality of 1-4 connection lines 121d may be disposed on the second insulating layer 115b. The plurality of 1-4 connection lines 121d may be electrically connected to the plurality of 1-3 connection lines 121c. For example, the 1-4 connection lines 121d may be electrically connected to the 1-3 connection lines 121c through contact holes of the second insulating layer 115b.

According to the present specification, a plurality of second connection lines 122 may be disposed on the second protective layer 113b in the non-display region NA. The plurality of second connection lines 122 may be lines for transmitting the signals transmitted from a flexible circuit board (or a flexible film) CB and the printed circuit board 160 (see FIG. 1) to the pad portion PAD to the pixel driving circuit PD of the display region AA. For example, the plurality of second connection lines 122 may be electrically connected to the plurality of pad electrodes PE to receive the signals from the flexible circuit board (or flexible film) CB and the printed circuit board.

For example, the plurality of second connection lines 122 may extend from the pad portion PAD toward the display region AA to transmit the signal to lines in the display region AA. In this case, the plurality of second connection lines 122 may function as link lines LL. The plurality of second connection lines 122 may include a 2-1 connection line 122a, a 2-2 connection line 122b, a 2-3 connection line 122c, and a 2-4 connection line 122d.

A plurality of 2-1 connection lines 122a may be disposed on the second protective layer 113b. The plurality of 2-1 connection lines 122a may extend from the second non-display region NA2 to the bending region BA and the first non-display region NA1. The plurality of 2-1 connection lines 122a may transmit signals transmitted from the flexible circuit board (or flexible film) CB and the printed circuit board to the pad portion PAD to the pixel driving circuit PD of the display region AA.

A plurality of 2-2 connection lines 122b may be disposed on the third protective layer 114. The plurality of 2-2 connection lines 122b may be disposed in the second non-display region NA2. The 2-2 connection lines 122b may be electrically connected to the 2-1 connection lines 122a through contact holes of the third protective layer 114. Accordingly, the signals from the flexible circuit board (or flexible film) CB and the printed circuit board may be transmitted to the 2-1 connection lines 122a through the 2-2 connection lines 122b.

The 2-3 connection lines 122c may be disposed on the first insulating layer 115a. The 2-3 connection lines 122c may be disposed in the second non-display region NA2. The 2-3 connection lines 122c may be electrically connected to the 2-2 connection lines 122b through contact holes of the first insulating layer 115a. Accordingly, the signals from the flexible circuit board (or flexible film) CB and the printed circuit board may be transmitted to the 2-1 connection lines 122a through the 2-3 connection lines 122c and the 2-2 connection lines 122b.

The 2-4 connection lines 122d may be disposed on the second insulating layer 115b. The 2-4 connection lines 122d may be disposed in the second non-display region NA2. The 2-4 connection lines 122d may be electrically connected to the 2-3 connection lines 122c through contact holes of the second organic insulating layer 115b. Accordingly, the signals from the flexible circuit board (or flexible film) CB and the printed circuit board may be transmitted to the 2-1 connection lines 122a through the 2-4 connection lines 122d, the 2-3 connection lines 122c, and the 2-2 connection lines 122b.

The plurality of first connection lines 121 and the plurality of second connection lines 122 may be formed of a conductive material having excellent flexibility or any one of various conductive materials used in the display region AA. For example, the second connection line 122 partially disposed in the bending region BA may be formed of a conductive material having excellent flexibility such as gold (Au), silver (Ag), aluminum (Al), or the like, but the embodiments of the present specification are not limited thereto. For example, the plurality of first connection lines 121 and the plurality of second connection lines 122 may be formed of molybdenum (Mo), chromium (Cr), titanium (Ti), nickel (Ni), neodymium (Nd), copper (Cu), and an alloy of silver (Ag) and magnesium (Mg), or an alloy thereof, but the embodiments of the present specification are not limited thereto.

A third insulating layer 115c may be disposed on the plurality of first connection lines 121 and the plurality of second connection lines 122. The third insulating layer 115c may be disposed in the remaining region excluding the bending region BA, but the embodiments of the present specification are not limited thereto. The third insulating layer 115c may be disposed in the display region AA, the first non-display region NA1, and the second non-display region NA2. A portion of the third insulating layer 115c disposed in the bending region BA may be removed. The third insulating layer 115c may be formed of an organic insulating material, but the embodiments of the present specification are not limited thereto. For other examples, the third insulating layer 115c may be formed of photoresist, polyimide (PI), a photo acrylic material, or the like, but the embodiments of the present specification are not limited thereto.

A plurality of banks BNK may be disposed on the third insulating layer 115c in the display region AA. The plurality of banks BNK may be disposed to overlap each of the plurality of subpixels. One or more light-emitting elements ED of the same type may be disposed on each of the plurality of banks BNK.

The plurality of signal lines TL may be disposed on the third insulating layer 115c in the display region AA. The plurality of signal line TL may be disposed in regions between the banks BNK. For example, the plurality of signal lines TL may be disposed adjacent to any one of the plurality of banks BNK.

The plurality of contact electrodes CCE may be disposed on the third insulating layer 115c in the display region AA. The plurality of contact electrodes CCE may supply the cathode voltage from the pixel driving circuit PD to the second electrode CE2.

The first electrode CE1 may be disposed on the bank BNK. For example, the first electrode CE1 may be disposed to extend from the adjacent signal line TL toward an upper portion of the bank BNK. The first electrode CE1 may be disposed on an upper surface of the bank BNK and a side surface of the bank BNK. For example, the first electrode CE1 may be disposed to extend from the signal line TL on the upper surface of the third insulating layer 115c to the side surface of the bank BNK and the upper surface of the bank BNK.

The first optical layers 117a surrounding the plurality of light-emitting elements ED in the display region AA may be disposed. For example, the first optical layers 117a may be disposed to cover the plurality of light-emitting elements ED and the plurality of banks BNK in a region of the plurality of subpixels. For example, the first optical layers 117a may cover the banks BNK, a portion of the passivation layer 116, and spaces between the plurality of light-emitting elements ED. The first optical layers 117a may be disposed between the plurality of light-emitting elements ED included in one pixel PX and between the plurality of banks BNK or may cover spaces between the plurality of light-emitting elements ED and between the plurality of banks BNK. For example, the first optical layers 117a may extend in the first direction (for example, the X-axis direction) and may be disposed spaced apart from each other in the second direction (for example, the Y-axis direction). For example, the first optical layer 117a may be disposed between the passivation layer 116 and the second electrode CE2 to surround side portions of the light-emitting element ED and the bank BNK, but the embodiments of the present disclosure are not limited thereto. For example, the first optical layer 117a may be a diffusion layer, a sidewall diffusion layer, or the like, but the embodiments of the present specification are not limited thereto.

The first optical layer 117a may include an organic insulating material in which fine particles are dispersed, but the embodiments of the present specification are not limited thereto. For example, the first optical layer 117a may be formed of siloxane in which fine metal particles such as titanium dioxide (TiO₂) particles are dispersed, but the embodiments of the present specification are not limited thereto. Light from the plurality of light-emitting elements ED may be scattered by the fine particles dispersed in the first optical layer 117a and emitted to the outside of the display device 1000. Accordingly, the first optical layer 117a may enhance the extraction efficiency of the light emitted from the plurality of light-emitting elements ED.

For example, the first optical layer 117a may be disposed on each of the plurality of pixels PX, or may be disposed together on some of the pixels PX disposed in the same row, but the embodiments of the present specification are not limited thereto. For example, the first optical layer 117a may be disposed on each of the plurality of pixels PX, or the plurality of pixels PX may share one first optical layer 117a. For another example, each of the plurality of subpixels may separately include the first optical layer 117a, but the embodiments of the present specification are not limited thereto.

Referring to the above-described plan view, the third optical layer 117c may be disposed between the first optical layers 117a. The third optical layer 117c may be disposed on the passivation layer 116 in the display region AA. For example, the third optical layer 117c may be disposed to surround the first optical layer 117a. For example, the third optical layer 117c may be in contact with a side surface of the first optical layer 117a. For example, the third optical layer 117c may be disposed in the region between the plurality of pixels PX. However, the embodiments of the present specification are not limited thereto. For example, the third optical layer 117c may be a diffusion layer, a diffusion layer window, a window diffusion layer, or the like, but the embodiments of the present specification are not limited thereto.

The third optical layer 117c may be formed of an organic insulating material, but the embodiments of the present specification are not limited thereto. The third optical layer 117c may be formed of the same material as the first optical layer 117a, but the embodiments of the present specification are not limited thereto. For example, the first optical layer 117a may include fine particles, and the third optical layer 117c may not include fine particles. For example, the third optical layer 117c may be formed of siloxane, but the embodiments of the present specification are not limited thereto.

For example, a thickness of the first optical layer 117a may be smaller than a thickness of the third optical layer 117c, but the embodiments of the present specification are not limited thereto. Accordingly, when viewed in a plan view, a region where the first optical layer 117a is disposed may include a concave portion recessed inward more than an upper surface of the third optical layer 117c.

According to the present specification, the second electrode CE2 may be disposed on the first optical layer 117a and the third optical layer 117c. For example, the second electrode CE2 may be electrically connected to the plurality of contact electrodes CCE through contact holes of the third optical layer 117c. The second electrode CE2 may be disposed on the plurality of light-emitting elements ED. For example, the second electrode CE2 may include a transparent conductive oxide such as indium tin oxide (ITO), indium zinc oxide (IZO), or the like, but the embodiments of the present specification are not limited thereto. For example, the second electrode CE2 may be disposed to be in contact with the cathode electrode 135. For example, the second electrode CE2 may overlap the first optical layer 117a. For example, the second electrode CE2 may cover an outer plane of the first optical layer 117a.

The second electrode CE2 may continuously extend in the first direction (for example, in the X-axis direction) of the substrate 110. Accordingly, the second electrode CE2 may be connected to the plurality of pixels PX, disposed in the first direction (for example, in the X-axis direction) of the substrate 110, in common. For example, the second electrode CE2 may be connected to the plurality of pixels PX in common.

According to the present specification, the second electrode CE2 may continuously extend on the first optical layer 117a, the third optical layer 117c, and the light-emitting element ED. The region where the first optical layer 117a is disposed may include a concave portion recessed inward more than the upper surface of the third optical layer 117c. Accordingly, a first portion of the second electrode CE2 disposed on the first optical layer 117a is disposed along the concave portion, and thus may be disposed at a lower position than a second portion of the second electrode CE2 disposed on the third optical layer 117c.

A second optical layer 117b may be disposed on the second electrode CE2. The second optical layer 117b may be disposed to overlap the plurality of light-emitting elements ED and the first optical layer 117a. Since the second optical layer 117b is disposed on the second electrode CE2 and the plurality of light-emitting elements ED, mura which may occur on some of the plurality of light-emitting elements ED may be improved. For example, when the plurality of light-emitting elements ED are transferred onto the substrate 110 of the display device 1000, a region where intervals between the plurality of light-emitting elements ED are not uniform may occur due to a process deviation or the like. When the intervals between the plurality of light-emitting elements ED are not uniform, a light-emitting region of each of the plurality of light-emitting elements ED may be disposed non-uniformly, and the mura may be visible to the user. Accordingly, since a second optical layer 117b configured to uniformly diffuse light on the plurality of light-emitting elements ED is disposed, it is possible to reduce light emitted from some of the light-emitting elements ED from being visible to the user as the mura. Accordingly, since the light emitted from the plurality of light-emitting elements ED is uniformly diffused by the second optical layer 117b and extracted to the outside of the display device 1000, the brightness uniformity of the display device 1000 may be enhanced.

The second optical layer 117b may be formed of an organic insulating material in which fine particles are dispersed, but the embodiments of the present specification are not limited thereto. For example, the second optical layer 117b may be formed of siloxane in which fine metal particles such as titanium dioxide (TiO₂) particles are dispersed, but the embodiments of the present specification are not limited thereto. For example, the second optical layer 117b may be formed of the same material as the first optical layer 117a, but the embodiments of the present specification are not limited thereto. For example, the second optical layer 117b may be a diffusion layer or an upper surface diffusion layer, but the embodiments of the present specification are not limited thereto.

According to the present specification, the light from the plurality of light-emitting elements ED may be scattered by the fine particles dispersed in the second optical layer 117b and emitted to the outside of the display device 1000. The second optical layer 117b may uniformly mix light emitted from the plurality of light-emitting elements ED to further enhance the brightness uniformity of the display device 1000. Further, the light extraction efficiency of the display device 1000 may be enhanced by light scattered from the plurality of fine particles, and accordingly, the display device 1000 may be driven at low power.

A black matrix BM may be disposed on the second electrode CE2, the first optical layer 117a, the third optical layer 117c, and the second optical layer 117b in the display region AA. For example, the black matrix BM may fill a contact hole of the third optical layer 117c. The black matrix BM is configured to cover the display region AA, and thus may reduce the color mixing of light of the plurality of subpixels and external light reflection. For example, the black matrix BM is also disposed in the contact hole to which the second electrode CE2 and the contact electrode CCE are connected, and thus may prevent light leakage between the plurality of neighboring subpixels.

For example, the black matrix BM may be formed of an opaque material, but the embodiments of the present specification are not limited thereto. For example, the black matrix BM may be an organic insulating material to which a black pigment or black dye is added, but the embodiments of the present specification are not limited thereto.

A cover layer 118 may be disposed on the black matrix BM in the display region AA. The cover layer 118 may protect configurations under the cover layer 118. For example, the cover layer 118 may be formed an organic insulating material, but the embodiments of the present specification are not limited thereto. For example, the cover layer 118 may be formed of photoresist, polyimide (PI), a photo acrylic material, or the like, but the embodiments of the present specification are not limited thereto. For example, the cover layer 118 may be an overcoating layer or an insulating layer, but the embodiments of the present specification are not limited thereto.

The polarization layer 293 may be disposed on the cover layer 118 via a first adhesive layer 291. The cover member 120 may be disposed on the polarization layer 293 via the second adhesive layer 295. For example, the first adhesive layer 291 and the second adhesive layer 295 may include an optically clear adhesive (OCA), an optically clear resin (OCR), a pressure sensitive adhesive (PSA), or the like, but the embodiments of the present specification are not limited thereto.

According to the present specification, the plurality of pad electrodes PE may be disposed on the third insulating layer 115c in the second non-display region NA2. For example, at least portions of the plurality of pad electrodes PE may be exposed from the passivation layer 116. For example, the plurality of pad electrodes PE may be electrically connected to the 2-4 connection lines 122d through contact holes of the third insulating layer 115c.

An adhesive layer ACF may be disposed on the plurality of pad electrodes PE. The adhesive layer ACF may be an adhesive layer in which conductive balls are dispersed in an insulating material, but the embodiments of the present specification are not limited thereto. When heat or pressure is applied to the adhesive layer ACF, since the conductive balls may be electrically connected at a portion to which the heat or pressure is applied, the adhesive layer ACF may have conductive properties. The flexible circuit board (or flexible film) CB may be attached or bonded to the plurality of pad electrodes PE by disposing the adhesive layer ACF between the plurality of pad electrodes PE and the flexible circuit board (or flexible film) CB. For example, the adhesive layer ACF may be an anisotropic conductive film (ACF), but the embodiments of the present specification are not limited thereto.

The flexible circuit board (or flexible film) CB may be disposed on the adhesive layer ACF. The flexible circuit board (or flexible film) CB may be electrically connected to the plurality of pad electrodes PE through the adhesive layer ACF. Accordingly, the signals output from the flexible circuit board (or flexible film) CB and the printed circuit board may be transmitted to the pixel driving circuit PD of the display region AA through the plurality of pad electrodes PE, the plurality of 2-4 connection lines 122d, the plurality of 2-3 connection lines 122c, the plurality of 2-2 connection lines 122b, and the plurality of 2-1 connection lines 122a.

FIG. 17 is a cross-sectional view showing the display device according to the embodiment of the present specification. FIG. 18 is a cross-sectional view showing the display device according to the embodiment of the present specification.

FIG. 17 is a cross-sectional view showing the subpixel including the light-emitting element disposed in the display region. FIG. 18 is a cross-sectional view showing the subpixel including the light-emitting element disposed in the non-display region. Configurations having substantially the same functions between the cross-sectional views are denoted by the same reference numerals, and repeated descriptions thereof will be omitted.

Referring to FIGS. 17 and 18, the first electrode CE1 may be formed of a plurality of conductive layers. For example, the first electrode CE1 may include a first conductive layer CE1a, a second conductive layer CE1b, a third conductive layer CE1c, and a fourth conductive layer CE1d, but the embodiments of the present specification are not limited thereto.

The first conductive layer CE1a may be disposed on the bank BNK. The second conductive layer CE1b may be disposed on the first conductive layer CE1a. The third conductive layer CE1c may be disposed on the second conductive layer CE1b. The fourth conductive layer CE1d may be disposed on the third conductive layer CE1c. For example, each of the first conductive layer CE1a, the second conductive layer CE1b, the third conductive layer CE1c, and the fourth conductive layer CE1d may be formed of titanium (Ti), molybdenum (Mo), aluminum (Al), or indium tin oxide (ITO), but the embodiments of the present specification are not limited thereto.

According to the present specification, some conductive layers having excellent reflection efficiency among the plurality of conductive layers constituting the first electrode CE1 may be configured as alignment keys and/or reflective plates for aligning the light emitting elements ED. For example, the second conductive layer CE1b among the plurality of conductive layers of the first electrode CE1 may include a reflective material. For example, the second conductive layer CE1b may include aluminum (Al), but the embodiments of the present specification are not limited thereto. Accordingly, the second conductive layer CE1b may be configured as a reflective plate. Further, identification in the manufacturing process may be easy due to the high reflective efficiency of the second conductive layer CE1b, and accordingly, a position or transfer position of the light-emitting element ED may be aligned based on the second conductive layer CE1b.

For example, in order to configure the second conductive layer CE1b as the reflective plate, the third conductive layer CE1c and the fourth conductive layer CE1d which cover the second conductive layer CE1b may be partially removed or etched. For example, portions of the third conductive layer CE1c and fourth conductive layer CE1d disposed on the bank BNK may be removed or etched to expose an upper surface of the second conductive layer CE1b. For example, in the third conductive layer CE1c and the fourth conductive layer CE1d, center portions and border portions (or edge portions) where a solder pattern SDP is disposed may be left, and the remaining portion may be removed. For example, the border portion (or edge portion) of each of the third conductive layer CE1c formed of titanium (Ti) and the fourth conductive layer CE1d formed of indium tin oxide (ITO) may not be etched. Accordingly, it is possible to prevent other conductive layers of the first electrode CE1 from being corroded by a tetramethylammonium hydroxide (TMAH) solution used in a mask process of the first electrode CE1.

According to the present specification, the first conductive layer CE1a and the third conductive layer CE1c may include titanium (Ti) or molybdenum (Mo). The second conductive layer CE1b may include aluminum (Al). The fourth conductive layer CE1d may include a transparent conductive oxide layer such as indium tin oxide (ITO) or indium zinc oxide (IZO) having excellent adhesion to the solder pattern SDP and having corrosion resistance and acid resistance. However, the embodiments of the present specification are not limited thereto.

The first conductive layer CE1a, the second conductive layer CE1b, the third conductive layer CE1c, and the fourth conductive layer CE1d may be sequentially deposited and then patterned by performing a photolithography process and an etching process, but the embodiments of the present specification are not limited thereto.

According to the present specification, the signal line TL, the contact electrode CCE, and the pad electrode PE disposed on the same layer as the first electrode CE1 may be formed of multi-layers made of a conductive material, but the embodiments of the present specification are not limited thereto. For example, the signal line TL, the contact electrode CCE, and the pad electrode PE may be formed of multi-layers of indium tin oxide (ITO)/titanium (Ti)/aluminum (Al)/titanium (Ti), but the embodiments of the present specification are not limited thereto.

According to the present specification, the solder pattern SDP may be disposed on the first electrode CE1 in each of the plurality of subpixels. The solder pattern SDP may bond the light-emitting element ED to the first electrode CE1. The first electrode CE1 and the light-emitting element ED may be electrically connected by eutectic bonding using the solder pattern SDP, but the embodiments of the present specification are not limited thereto. The first electrode CE1 and the anode electrode 134 of the light-emitting element ED may be electrically connected in a eutectic bonding manner using the solder pattern SDP, but the embodiments of the present specification are not limited thereto.

For example, when the solder pattern SDP is formed of indium (In) and the anode electrode 134 of the light-emitting element ED is formed of gold (Au), the solder pattern SDP and the anode electrode 134 may be bonded by applying heat and pressure during the transfer process of the light-emitting element ED. The light-emitting element ED may be bonded to the solder pattern SDP and the first electrode CE1 by eutectic bonding without a separate adhesive. For example, the solder pattern SDP may be formed of indium (In), tin (Sn), or an alloy thereof, but the embodiments of the present specification are not limited thereto. For example, the solder pattern SDP may be a bonding pad or a joining pad, but the embodiments of the present specification are not limited thereto.

According to the present specification, the passivation layer 116 may be disposed on the plurality of signal lines TL, the plurality of first electrodes CE1, the plurality of contact electrodes CCE, and the third insulating layer 115c. For example, the passivation layer 116 may be disposed in the display region AA, the first non-display region NA1, and the second non-display region NA2. A portion of the passivation layer 116 disposed in the bending region BA may be removed. A portion of the passivation layer 116 covering the plurality of pad electrodes PE in the second non-display region NA2 may be removed. Since the passivation layer 116 is disposed to cover the remaining region excluding regions where the bending region BA, the plurality of pad electrodes PE, and the solder pattern SDP are disposed, permeation of moisture or impurities into the light-emitting element ED may be reduced.

For example, the passivation layer 116 may be formed of a single layer or multi-layers made of silicon oxide (SiOₓ) or silicon nitride (SiNₓ), but the embodiments of the present specification are not limited thereto. For example, the passivation layer 116 may be a protective layer or an insulating layer, but the embodiments of the present specification are not limited thereto. For example, the passivation layer 116 may include a hole 116h which exposes the solder pattern SDP.

The light-emitting element ED may be disposed on the solder pattern SDP in each of the plurality of subpixels. The first light-emitting element 130 may be disposed in the first subpixel SP1. The second light-emitting element 140 may be disposed in the second subpixel SP2. The third light-emitting element 150 may be disposed in the third subpixel SP3.

The light-emitting element ED may be formed on a silicon wafer by a metal organic chemical vapor deposition (MOCVD) method, a chemical vapor deposition (CVD) method, a plasma-enhanced chemical vapor deposition (PECVD) method, a molecular beam epitaxy (MBE) method, a hydride vapor phase epitaxy (HVPE) method, a sputtering method, or the like, but the embodiments of the present specification are not limited thereto.

The first light-emitting element 130 may include the anode electrode 134, a first semiconductor layer 131, an active layer 132, a second semiconductor layer 133, the cathode electrode 135, and an encapsulation film 136, but the embodiments of the present specification are not limited thereto. For example, the first light-emitting element 130 may not include the encapsulation film 136.

The first semiconductor layer 131 may be disposed on the solder pattern SDP. The second semiconductor layer 133 may be disposed on the first semiconductor layer 131.

For example, one of the first semiconductor layer 131 and the second semiconductor layer 133 may be implemented with a compound semiconductor of group III-V, group II-VI, or the like, and may be doped with impurities (or a dopant). For example, one of the first semiconductor layer 131 and the second semiconductor layer 133 may be a semiconductor layer doped with n-type impurities and the other may be a semiconductor layer doped with p-type impurities, but the embodiments of the present specification are not limited thereto. For example, one or more of the first semiconductor layer 131 and the second semiconductor layer 133 may be layers in which a material such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), gallium arsenide (GaAs), or the like is doped with n-type impurities or p-type impurities, but the embodiments of the present specification are not limited thereto. For example, the n-type impurities may be silicon (Si), germanium (Ge), selenium (Sc), carbon (C), tellurium (Te), tin (Sn), or the like, but the embodiments of the present specification are not limited thereto. For example, the p-type impurities may be magnesium (Mg), zinc (Zn), calcium (Ca), strontium (Sr), barium (Ba), beryllium (Be), or the like, but the embodiments of the present specification are not limited thereto.

For example, the first semiconductor layer 131 and the second semiconductor layer 133 may be a nitride semiconductor containing n-type impurities and a nitride semiconductor containing p-type impurities, respectively, but the embodiments of the present specification are not limited thereto. For example, the first semiconductor layer 131 may be a nitride semiconductor containing p-type impurities, and the second semiconductor layer 133 may be a nitride semiconductor containing n-type impurities, but the embodiments of the present specification are not limited thereto.

The active layer 132 may be disposed between the first semiconductor layer 131 and the second semiconductor layer 133. The active layer 132 may receive holes and electrons from the first semiconductor layer 131 and the second semiconductor layer 133 and emit light. For example, the active layer 132 may include any one of a single well structure, a multi-well structure, a single quantum well structure, a multi quantum well (MQW) structure, a quantum dot structure, or a quantum line structure, but the embodiments of the present specification are not limited thereto. For example, the active layer 132 may be formed of indium gallium nitride (InGaN) or gallium nitride (GaN), but the embodiments of the present specification are not limited thereto.

For another example, the active layer 132 may include a multi quantum well (MQW) structure having a well layer and a barrier layer having a higher band gap than the well layer. For example, the active layer 132 may configure InGaN as the well layer and configure an AlGaN layer as the barrier layer, but the embodiments of the present specification are not limited thereto.

The anode electrode 134 may be disposed between the first semiconductor layer 131 and the solder pattern SDP. For example, the anode electrode 134 may electrically connect the first semiconductor layer 131 and the first electrode CE1. The anode voltage output from the pixel driving circuit PD may be applied to the first semiconductor layer 131 through the signal line TL, the first electrode CE1, and the anode electrode 134. For example, the anode electrode 134 may be formed of a conductive material which may be eutectically bonded to the solder pattern SDP, but the embodiments of the present specification are not limited thereto. For example, the anode electrode 134 may be formed of gold (Au), tin (Sn), tungsten (W), silicon (Si), silver (Ag), titanium (Ti), iridium (Ir), chromium (Cr), indium (In), zinc (Zn), lead (Pb), nickel Ni), platinum (Pt), and copper (Cu), or an alloy thereof, but the embodiments of the present specification are not limited thereto.

The cathode electrode 135 may be disposed on the second semiconductor layer 133. For example, the cathode electrode 135 may electrically connect the second semiconductor layer 133 and the second electrode CE2. The cathode voltage output from the pixel driving circuit PD may be applied to the second semiconductor layer 133 through the contact electrode CCE, the second electrode CE2, and the cathode electrode 135. The cathode electrode 135 may be formed of a transparent conductive material so that light emitted from the light-emitting element ED may be directed to an upper portion of the light-emitting element ED, but the embodiments of the present specification are not limited thereto. For example, the cathode electrode 135 may be formed of a material such as indium tin oxide (ITO), indium zinc oxide (IZO), or indium gallium zinc oxide (IGZO), but the embodiments of the present specification are not limited thereto.

The encapsulation film 136 may be disposed on at least portions of the first semiconductor layer 131, the active layer 132, the second semiconductor layer 133, the anode electrode 134, and the cathode electrode 135. For example, the encapsulation film 136 may surround at least portions of the first semiconductor layer 131, the active layer 132, the second semiconductor layer 133, the anode electrode 134, and the cathode electrode 135.

For example, the encapsulation film 136 may protect the first semiconductor layer 131, the active layer 132, and the second semiconductor layer 133. For example, the encapsulation film 136 may be disposed on a side surface of the first semiconductor layer 131, a side surface of the active layer 132, and a side surface of the second semiconductor layer 133.

For example, the encapsulation film 136 may be disposed on at least portions of the anode electrode 134 and the cathode electrode 135, for example, an edge portion (or a border portion or one side) of the anode electrode 134 and an edge portion (or a border portion or one side) of the cathode electrode 135. Since at least a portion of the anode electrode 134 may be exposed from the encapsulation film 136, the anode electrode 134 and the solder pattern SDP may be connected. For example, since at least a portion of the cathode electrode 135 may be exposed from the encapsulation film 136, the cathode electrode 135 and the second electrode CE2 may be connected. For example, the encapsulation film 136 may be formed of an insulating material such as silicon nitride (SiNₓ) or silicon oxide (SiOₓ), but the embodiments of the present specification are not limited thereto.

For another example, the encapsulation film 136 may have a structure in which a reflective material is dispersed in a resin layer, but the embodiments of the present specification are not limited thereto. For example, the encapsulation film 136 may be manufactured as a reflector of various structures, but the embodiments of the present specification are not limited thereto. Since light emitted from the active layer 132 may be reflected upward by the encapsulation film 136, light extraction efficiency may be enhanced. For example, the encapsulation film 136 may be a reflective layer, but the embodiments of the present specification are not limited thereto.

According to the present specification, although the light-emitting element ED is described as having a vertical structure, the embodiments of the present specification are not limited thereto. For example, the light-emitting element ED may have a lateral structure or a flip chip structure.

Although the first light-emitting element 130 has been described, the second light-emitting element 140 and the third light-emitting element 150 may have substantially the same structure as the first light-emitting element 130. For example, the second light-emitting element 140 and the third light-emitting element 150 may be substantially the same as the first semiconductor layer 131, the active layer 132, the second semiconductor layer 133, the anode electrode 134, the cathode electrode 135, and the encapsulation film 136 of the first light-emitting element 130.

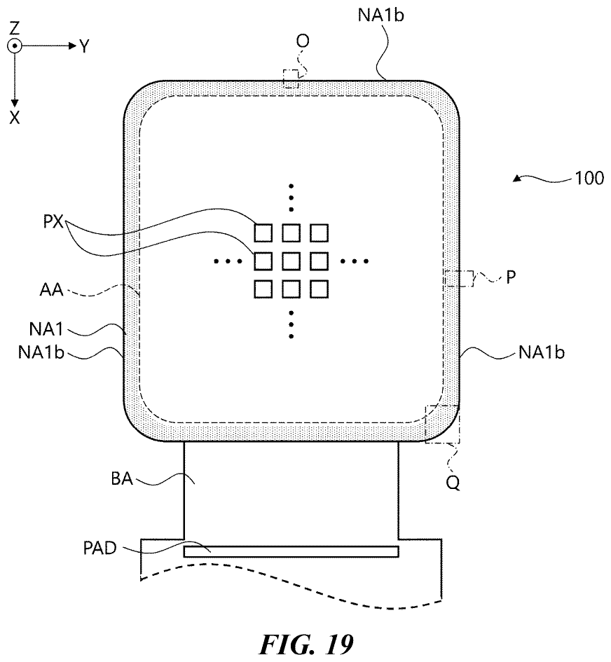

FIGS. 19 to 21 are plan views showing the display device according to the embodiment of the present specification. FIGS. 26 to 29 are plan views showing the display device according to the embodiment of the present specification.

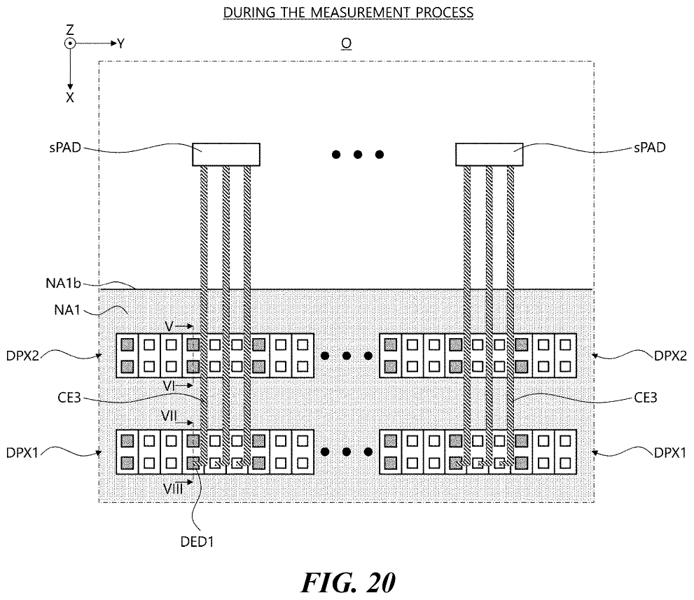

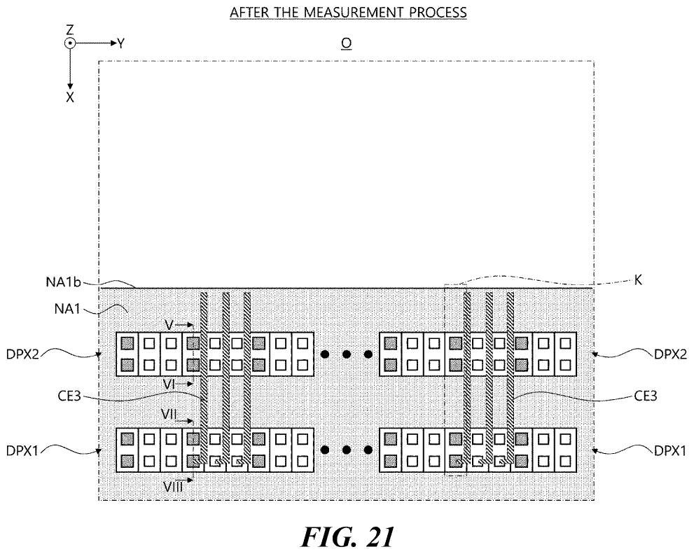

FIGS. 20 and 21 are partially enlarged views of portion O in FIG. 19. FIGS. 26 and 27 are partially enlarged views of portion P in FIG. 19. FIGS. 28 and 29 are partially enlarged views of portion Q in FIG. 19.

FIG. 20, FIG. 26, and FIG. 28 show the display device during the measurement process. FIG. 21, FIG. 27, and FIG. 29 show the display device after the measurement process.

In the present specification, in order to acquire a measurement value substantially the same as or similar to a physical property value of the light-emitting element disposed in the display region, a third electrode CE3 is separately disposed on the dummy light-emitting element. Both the second electrode disposed in the display region and the third electrode CE3 disposed in the first non-display region NA may be disposed on substantially the same light-emitting element. Accordingly, a physical property value of the dummy light-emitting element may be measured to infer the physical property value of the light-emitting element disposed in the display region.

Referring to FIG. 20, the display device may include the first non-display region NA1 including the border NA1b. The first non-display region NA1 may include a first dummy pixel DPX1 in which the third electrode CE3 is disposed, and a second dummy pixel DPX2 disposed between the first dummy pixel DPX1 and the border NAb1.

The first dummy pixel DPX1 may include a first dummy light-emitting element DED1 and the third electrode CE3 disposed on the first dummy light-emitting element DED1. During the measurement process, a separate pad sPAD may be connected to the third electrode CE3 disposed on the first dummy light-emitting element DED1 to measure an information item of the first dummy light-emitting element DED1.

Referring to FIG. 21, the separate pad sPAD may be removed in the process after testing (after the measurement process).

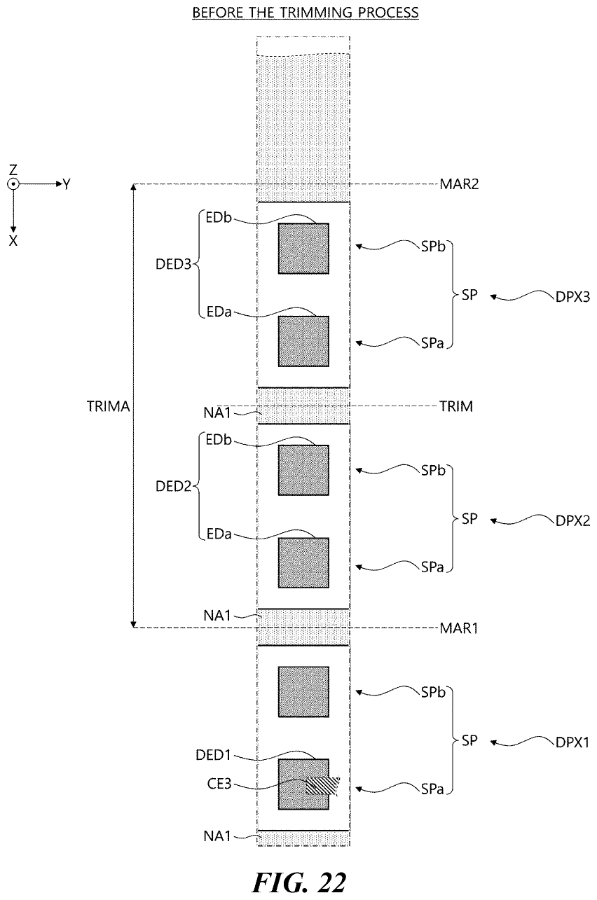

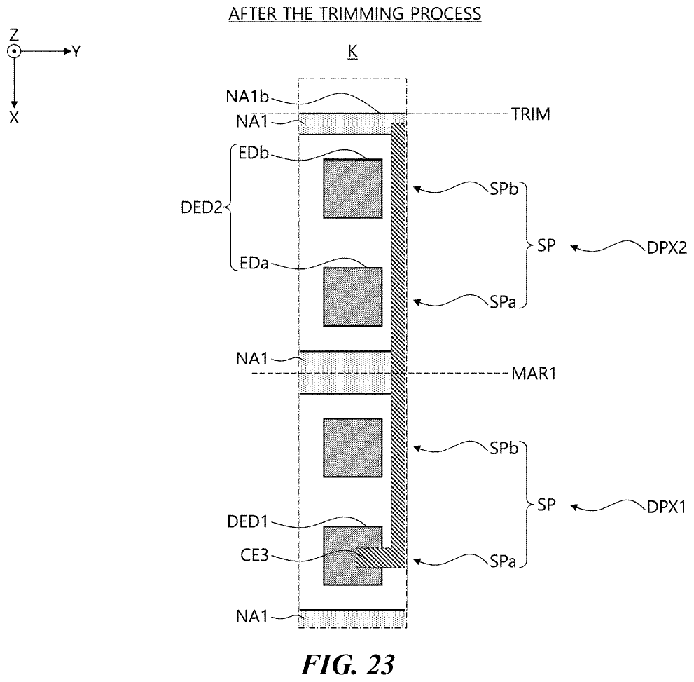

FIG. 22 is a plan view showing the display device according to the embodiment of the present specification before being trimmed (before a trimming process). FIG. 23 is a plan view showing the display device according to the embodiment of the present specification after being trimmed (after the trimming process). FIG. 23 is a partially enlarged view showing portion K in FIG. 21.

Referring to FIG. 22, the display device before being trimmed may include the first non-display region NA1 where the dummy pixels DPX1, DPX2, and DPX3 including a plurality of dummy light-emitting elements DED1, DED2, and DED3 are disposed.

In the state before the display device according to the embodiment is trimmed, errors or the like are corrected according to a trimming process in the manufacturing process. For example, precision is enhanced by correcting errors which may occur in the trimming process. For example, the completeness of the display device is enhanced so that the remaining portion excluding at least a portion of the display device damaged by trimming may be utilized. For example, a space is secured in which additional processing or the like is performed when the additional processing, or the like is required after trimming. The trimming process may be a separate process which is distinguished from the measurement process, but is not limited thereto. For example, the trimming process may be performed along with the measurement process.

Accordingly, before trimming, in addition to an actually trimmed line TRIM, a first margin line MARI is formed inside the actually trimmed line TRIM (for example, in the X-axis direction) and a second margin line MAR2 disposed outside the actually trimmed line TRIM. The actually trimmed line TRIM may become a border of the first non-display region NA1 after trimming. The first margin line MAR1 and the second margin line MAR2 are virtual lines and may define an error range of a region which may be in contact with the panel when a trimming device of the display panel actually trims the panel. The trimming device of the display panel may trim only a region between the first margin line MAR1 and the second margin line MAR2.

The display device according to the embodiment of the present specification may include the first dummy pixel DPX1 disposed inside the first margin line MAR1. The first dummy pixel DPX1 may include the first dummy light-emitting element DED1 and the third electrode CE3 disposed on the first dummy light-emitting element DED1.

The display device according to the embodiment of the present specification may include the second dummy pixel DPX2 disposed between the first margin line MAR1 and the actually trimmed line TRIM. The second dummy pixel DPX2 may include a second dummy light-emitting element DED2.

The display device according to the embodiment of the present specification may include a third dummy pixel DPX3 disposed between the actually trimmed line TRIM and the second margin line MAR2. The third dummy pixel DPX3 may include a third dummy light-emitting element DED3.

Each of the dummy pixels DPX1, DPX2, and DPX3 may refer to a dummy pixel disposed in an inner region of the first margin line MAR1, in a region between the first margin line MAR1 and the actually trimmed line TRIM, and in a region between the actually trimmed line TRIM and the second margin line MAR2. Although only one dummy pixel is shown in each region in the drawing, each of the first dummy pixel DPX1, the second dummy pixel DPX2, and the third dummy pixel DPX3 may be a plurality of dummy pixels. For example, a plurality of second dummy pixels DPX2 may be disposed in the region between the first margin line MAR1 and the actually trimmed line TRIM.

Conventionally, the physical property value of the dummy light-emitting element was inferred by disposing the third electrode CE3 in the third dummy pixel DPX3 disposed between the actually trimmed line TRIM and the second margin line MAR2. In this case, since the third dummy pixel DPX3 is not present in the first non-display region NA1 of the final product after being trimmed, it was impossible to pre-extract information items of an individual dummy light light-emitting element including resistance according to an I-V curve. Further, there was a problem that it was impossible to periodically monitor information items after being trimmed.

In the display device according to the embodiment of the present specification, the third electrode CE3 is disposed in the first dummy pixel DPX1 disposed inside the first margin line MAR1. Accordingly, the information items of the individual dummy light-emitting element may be extracted in a process of forming the second electrode disposed on the light-emitting element of the display region in the display region. Information items of the light-emitting element in the display region may be inferred from the information items of the dummy light-emitting element.

Referring to FIG. 23, the actually trimmed line TRIM may form the border NA1b of the first non-display region NA1 after being trimmed. The display device according to the embodiment of the present specification may include the first dummy pixel DPX1 including the first dummy light-emitting element DED1 and the third electrode CE3 disposed on the first dummy light-emitting element DED1, and the second dummy pixel DPX2 disposed between the border NA1b of the first non-display region NA1 and the first dummy pixel DPX1.

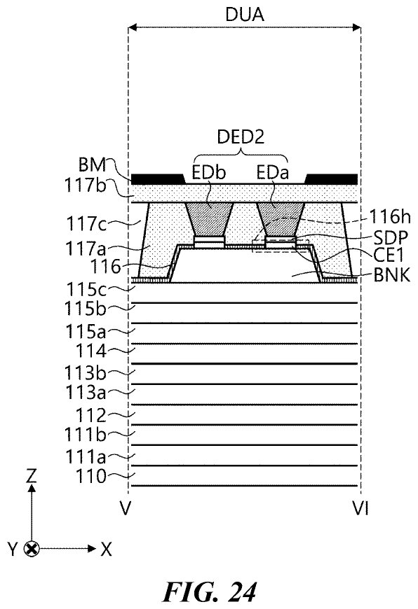

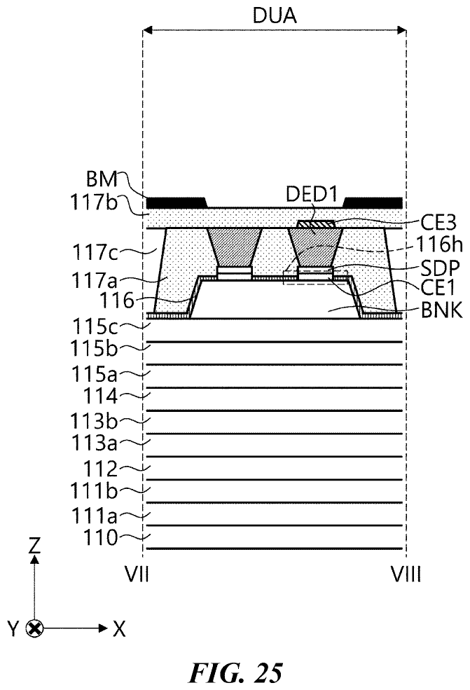

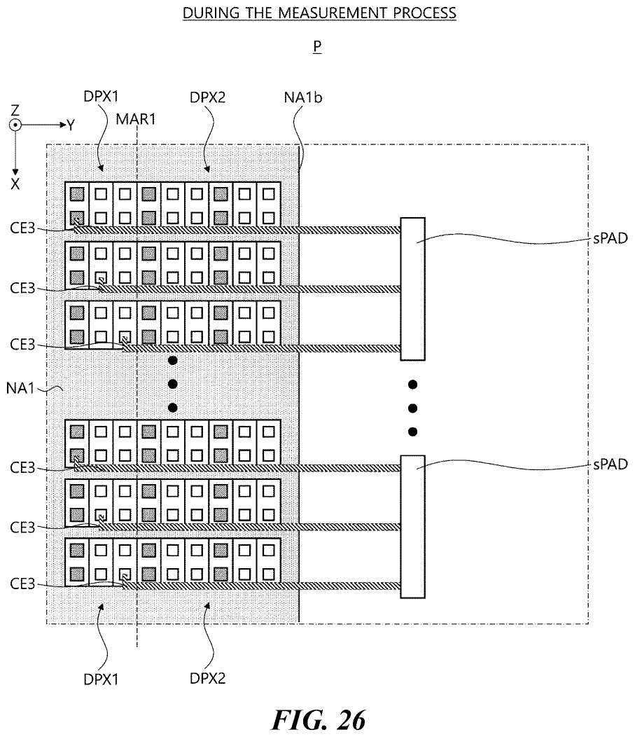

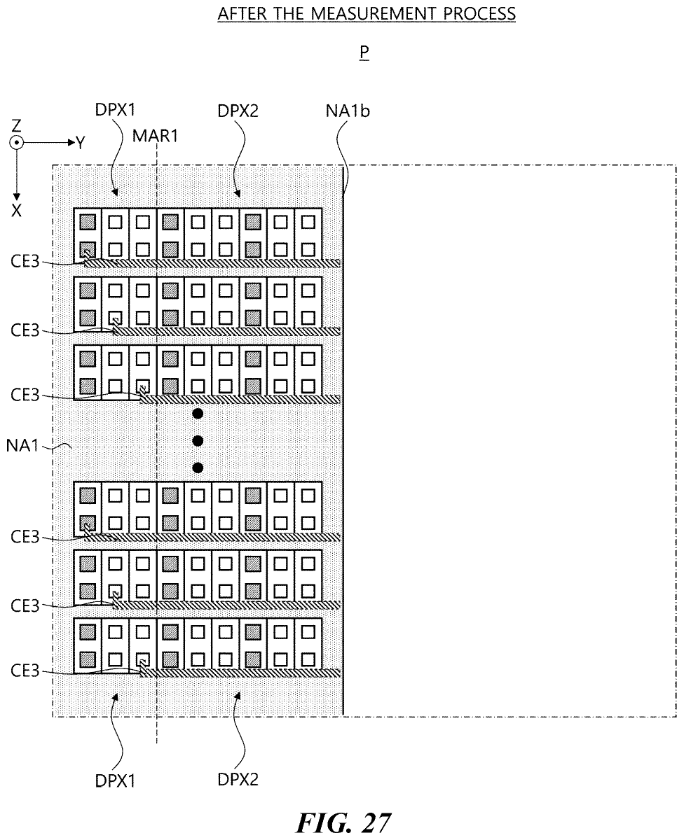

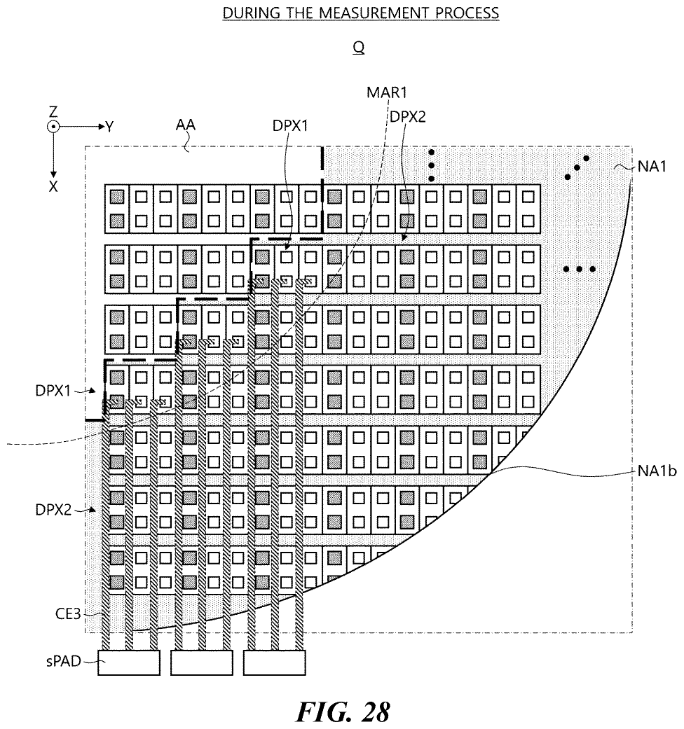

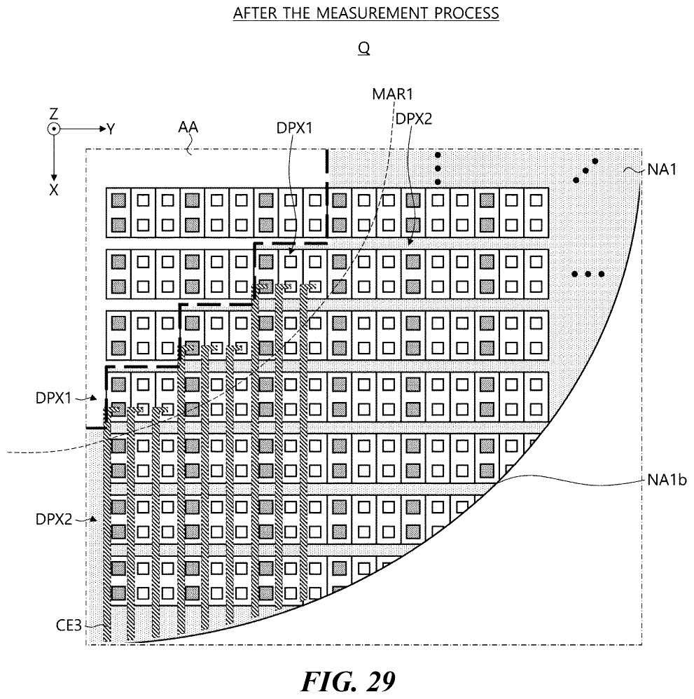

FIGS. 24 and 25 are cross-sectional views showing the display device according to the embodiment of the present specification. FIG. 24 is a cross-sectional view taken along line V-VI in FIG. 20. FIG. 25 is a cross-sectional view taken along line VII-VIII in FIG. 20. Configurations having substantially the same functions as the above-described embodiment (for example, FIG. 14) are denoted by the same reference numerals, and repeated descriptions thereof will be omitted.

Referring to FIG. 24, the second optical layer 117b may be disposed on the second dummy light-emitting element DED2.

Referring to FIG. 25, the third electrode CE3 may be disposed on the first dummy light-emitting element DED1. During the measurement process, the third electrode CE3 may perform substantially the same function as the second electrode disposed on the light-emitting element of the display region. For example, the third electrode CE3 may supply the cathode voltage to the first dummy light-emitting element DED1 during the measurement process.

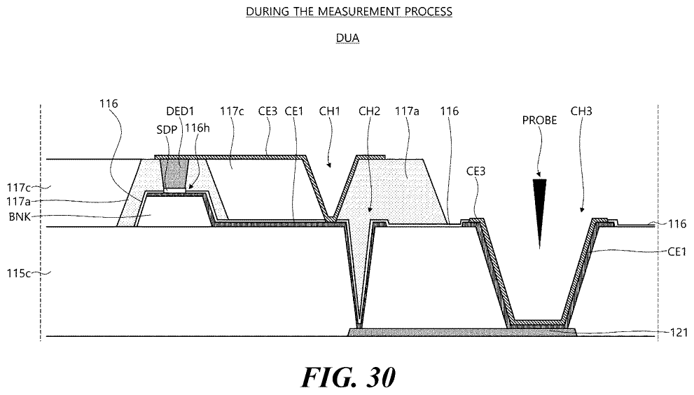

FIG. 30 is a cross-sectional view showing the display device according to the embodiment of the present specification. FIG. 30 shows the display device during the measurement process.

Referring to FIG. 30, the third insulating layer 115c of the first non-display region including the dummy region DUA may include a second contact hole CH2 and a third contact hole CH3. The bank BNK may be disposed on the third insulating layer 115c. The first electrode CEI may be disposed on the bank BNK. The first dummy light-emitting element DED1 may be disposed on the first electrode CE1, and the solder pattern SDP may be disposed between the first dummy light-emitting element DED1 and the first electrode CE1. The solder pattern SDP may electrically connect the first electrode CE1 and the first dummy light-emitting element DED1 by a eutectic bonding manner.

The passivation layer 116 including the hole 116h which exposes the first electrode CE1 may be disposed on the first electrode CE1. The optical layers 117a and 117c surrounding the first dummy light-emitting element DED1 may be disposed on the third insulating layer 115c. A first contact hole CH1 may be formed in the optical layers 117a and 117c.

During the measurement process, the third electrode CE3 may be connected to the first electrode CE1 through the first contact hole CH1. The first electrode CE1 may be connected to the first connection line 121 through the second contact hole CH2.

In one embodiment, the first connection line 121 may include the above-described 1-1 connection line to 1-4 connection line 121a, 121b, 121c, and 121d. In some implementations, the first connection line 121 may be the 1-4 connection line 121d.

The first connection line 121 may be connected to the first electrode CE1 through the third contact hole CH3, and the first electrode CE1 may be connected to the third electrode CE3. A probe PROBE used for measurement may be in contact with the third electrode CE3 disposed in the third contact hole CH3.

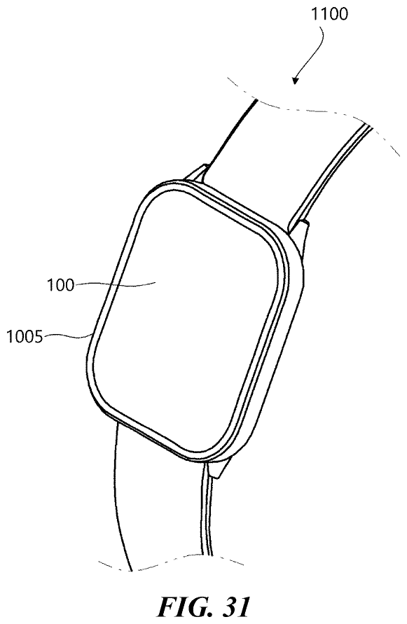

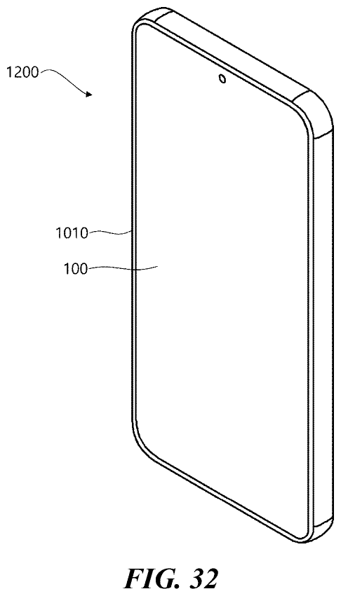

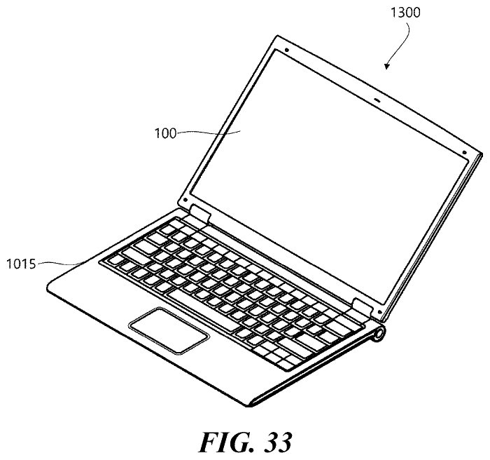

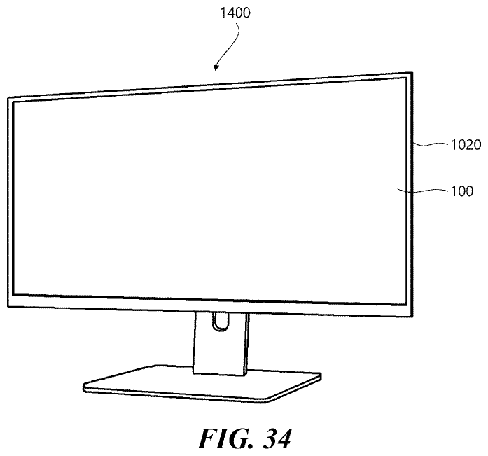

FIGS. 31 to 34 are views showing devices to which the display device according to the embodiments of the present specification is applied.

Referring to FIGS. 31 to 34, the display devices 1000 according to the embodiments of the present specification may be included in various devices or electronic devices. For example, various electronic devices may include a wearable device 1100, a mobile device 1200, a notebook 1300, and a monitor or television (TV) 1400, but the embodiments of the present specification are not limited thereto.

The wearable device 1100, the mobile device 1200, the notebook 1300, and the monitor or TV 1400 may include case portions 1005, 1010, 1015, and 1020, respectively, and may each include the above-described display panel 100 and display device 1000 according to the embodiments of the present specification.

For example, the display device according to the embodiment of the present specification may be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an electronic book, a portable multimedia player (PMP), a personal digital assistant (PDA), an MP3 player, a mobile medical apparatus, a desktop personal computer (PC), a laptop PC, a netbook computer, a workstation, a navigation device, a vehicle display device, a theater display device, a television, a wallpaper apparatus, a signage apparatus, a gaming apparatus, a notebook, a monitor, a camera, a camcorder, a home appliance, and the like.

The display device according to one or more embodiments of the present specification may be described as follows.

A display device according to the embodiment of the present specification may include a display region including a light-emitting element and a second electrode disposed on the light-emitting element, and a non-display region including a first dummy light-emitting element and a third electrode disposed on the first dummy light-emitting element, and surrounding the display region, wherein the non-display region may further include a second dummy light-emitting element disposed between a border of the non-display region and the first dummy light-emitting element.

According to various embodiments of the present specification, the non-display region may further include a first electrode, and the first dummy light-emitting element may be disposed between the first electrode and the third electrode of the non-display region.

According to various embodiments of the present specification, the non-display region may further include an optical layer surrounding the first dummy light-emitting element.

According to various embodiments of the present specification, the non-display region may further include a bank, and the first electrode may be disposed between the bank and the first dummy light-emitting element.

According to various embodiments of the present specification, the non-display region may further include a solder pattern disposed between the first electrode and the first dummy light-emitting element.

According to various embodiments of the present specification, the non-display region may further include a passivation layer disposed between the bank and the first dummy light-emitting element, and the passivation layer may include a hole that exposes the solder pattern.

According to various embodiments of the present specification, the first electrode of the non-display region may be disposed between the bank and the solder pattern.

According to various embodiments of the present specification, the second electrode and the third electrode may supply a cathode voltage.

According to various embodiments of the present specification, the display region may further include a pixel driving circuit including a plurality of pixel circuits, and the light-emitting element may include an inorganic light-emitting element driven by the pixel driving circuit.

According to various embodiments of the present specification, the display region may further include an optical layer surrounding the inorganic light-emitting element.

According to various embodiments of the present specification, the display region may further include a passivation layer disposed between the pixel driving circuit and the inorganic light-emitting element.

According to various embodiments of the present specification, the display region may further include a bank disposed between the pixel driving circuit and the passivation layer.

According to various embodiments of the present specification, the display region may further include a solder pattern disposed between the bank and the inorganic light-emitting element, and the passivation layer may include a hole that exposes the solder pattern.

According to various embodiments of the present specification, the display region may further include a first electrode, the inorganic light-emitting element may be disposed between the first electrode and the second electrode, and the first electrode may be disposed between the bank and the solder pattern.

According to various embodiments of the present specification, the optical layer may include a first optical layer disposed between a plurality of subpixels and a second optical layer disposed on the first optical layer.

According to various embodiments of the present specification, the display region may further include a first electrode, the light-emitting element may be disposed between the first electrode and the second electrode, and the light-emitting element may include an anode electrode, a first semiconductor layer disposed on the anode electrode, an active layer disposed on the first semiconductor layer, a second semiconductor layer disposed on the active layer, and a cathode electrode disposed on the second semiconductor layer.

According to various embodiments of the present specification, the light-emitting element may have a vertical structure.

According to various embodiments of the present specification, the display device may further include a solder pattern disposed between the first electrode and the anode electrode, wherein the first electrode and the anode electrode may be electrically connected by eutectic bonding using the solder pattern.

According to various embodiments of the present specification, the light-emitting element may be a micro light-emitting diode (LED).

A display device according to the embodiment of the present specification may include a display region including a plurality of pixels, and a non-display region including a first dummy pixel and a second dummy pixel and surrounding the display region, wherein each of the plurality of pixels may include a first subpixel including a 1-1 subpixel and a 1-2 subpixel that implement a first color, a second subpixel including a 2-1 subpixel and a 2-2 subpixel that implement a second color, and a third subpixel including a 3-1 subpixel and a 3-2 subpixel that implement a third color, the first dummy pixel may include a first dummy light-emitting element and a third electrode disposed on the first dummy light-emitting element, and the second dummy pixel may be disposed between a border of the non-display region and the first dummy pixel.

A method of manufacturing the display device according to an embodiment of the present specification may comprise inspecting whether a defect of the light-emitting element is presented or not in each specific operation of a manufacturing process of the display device; and if the defect is presented, then removing the defect before moving on to a next process, wherein the inspecting whether the defect is presented or not comprises inferring a physical property value of the light-emitting element based on measurement of a physical property value of the first dummy light-emitting element.

According to the present specification, since a display device is protected from moisture permeation from the outside, the reliability of the display device can be enhanced.

According to the present specification, since the moisture permeation from the outside of a display device is prevented, the lifespan of the display device can be enhanced. Accordingly, power consumption can be reduced and low-power driving can be performed in the long term.

According to the present specification, it is possible to perform an inspection every time a specific operation is performed in a manufacturing process. Accordingly, a cause of a problem can be identified and additional measures can be taken before moving on to a next process for defects.

According to the present specification, information items for light-emitting element of a display panel can be easily extracted.

The effects according to the present specification are not limited to the above-mentioned effects, and other effects which are not mentioned can be clearly understood by those skilled in the art from the disclosure to be described below.

Accordingly, the embodiments disclosed in the present disclosure are not intended to limit the technical spirit of the present disclosure, but intended to describe the same, and the scope of the technical spirit of the present disclosure is not limited by these embodiments.

Accordingly, the embodiments disclosed in the present disclosure are not intended to limit the technical spirit of the present disclosure but illustrate it, and the scope of the technical spirit of the present specification is not limited by these embodiments.

Accordingly, the above-described embodiments should be understood as exemplary in all aspects and not restrictive.

Accordingly, the above-described embodiments should be understood in all respects as illustrative and not restrictive.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a display region including a light-emitting element and a first electrode disposed on the light-emitting element; and
a non-display region including a first dummy light-emitting element and a second electrode disposed on the first dummy light-emitting element, and the non-display region surrounding the display region,
wherein the non-display region includes a second dummy light-emitting element disposed between a border of the non-display region and the first dummy light-emitting element.

2. The display device of claim 1, wherein the non-display region further includes a third electrode, and
the first dummy light-emitting element is disposed between the third electrode and the second electrode of the non-display region.

3. The display device of claim 2, wherein the non-display region further includes an optical layer surrounding the first dummy light-emitting element.

4. The display device of claim 3, wherein the non-display region further includes a bank, and
the third electrode is disposed between the bank and the first dummy light-emitting element.

5. The display device of claim 4, wherein the non-display region further includes a solder pattern disposed between the third electrode and the first dummy light-emitting element.

6. The display device of claim 5, wherein the non-display region further includes a passivation layer disposed between the bank and the first dummy light-emitting element, and
the passivation layer includes a hole that exposes the solder pattern.

7. The display device of claim 6, wherein the third electrode of the non-display region is disposed between the bank and the solder pattern.

8. The display device of claim 1, wherein the first electrode and the second electrode are configured to supply a cathode voltage.

9. The display device of claim 1, wherein the display region further includes a pixel driving circuit including a plurality of pixel circuits, and
the light-emitting element includes an inorganic light-emitting element driven by the pixel driving circuit.

10. The display device of claim 9, wherein the display region further includes an optical layer surrounding the inorganic light-emitting element.

11. The display device of claim 9, wherein the display region further includes a passivation layer disposed between the pixel driving circuit and the inorganic light-emitting element.

12. The display device of claim 11, wherein the display region further includes a bank disposed between the pixel driving circuit and the passivation layer.

13. The display device of claim 12, wherein the display region further includes a solder pattern disposed between the bank and the inorganic light-emitting element, and
the passivation layer includes a hole that exposes the solder pattern.

14. The display device of claim 13, wherein the display region further includes a third electrode,
the inorganic light-emitting element is disposed between the third electrode and the first electrode, and
the third electrode is disposed between the bank and the solder pattern.

15. The display device of claim 10, wherein the optical layer includes a first optical layer disposed between a plurality of subpixels and a second optical layer disposed on the first optical layer.

16. The display device of claim 1, wherein the display region further includes a third electrode,
the light-emitting element is disposed between the third electrode and the first electrode, and
the light-emitting element includes:
an anode electrode;
a first semiconductor layer disposed on the anode electrode;
an active layer disposed on the first semiconductor layer;
a second semiconductor layer disposed on the active layer; and
a cathode electrode disposed on the second semiconductor layer.

17. The display device of claim 16, wherein the light-emitting element has a vertical structure.

18. The display device of claim 16, further comprising a solder pattern disposed between the third electrode and the anode electrode,
wherein the third electrode and the anode electrode are electrically connected by eutectic bonding using the solder pattern.

19. The display device of claim 16, wherein the light-emitting element is a micro light-emitting diode.

20. The display device of claim 15, wherein the second optical layer is disposed on the first electrode and the inorganic light-emitting element.

21. A display device comprising:
a display region including a plurality of pixels; and
a non-display region including a first dummy pixel and a second dummy pixel and surrounding the display region,
wherein each of the plurality of pixels includes:
a first subpixel including a 1-1 subpixel and a 1-2 subpixel that are configured to emit a first color;
a second subpixel including a 2-1 subpixel and a 2-2 subpixel that are configured to emit a second color; and
a third subpixel including a 3-1 subpixel and a 3-2 subpixel that are configured to emit a third color,
wherein the first dummy pixel includes a first dummy light-emitting element and a first electrode disposed on the first dummy light-emitting element, and
wherein the second dummy pixel is disposed between a border of the non-display region and the first dummy pixel.

22. A method of manufacturing the display device according to claim 1, comprising:
inspecting whether a defect of the light-emitting element is present or not in an operation of a manufacturing process of the display device; and
in a case that the defect is present, removing the defect before moving on to a next process,
wherein the inspecting whether the defect is present or not comprises inferring a physical property value of the light-emitting element based on measurement of a physical property value of the first dummy light-emitting element.
